(19) United States
(12) Patent Application Publication
(10) Pub. No.: US 2023/0058225 A1
(43) Pub. Date: Feb. 23, 2023

(54) VERTICAL TRANSISTOR DEVICE

(71) Applicant: Tokyo Electron Limited, Tokyo (JP)

(72) Inventors: Mark I. Gardner, Albany, NY (US); H. Jim Fulford, Albany, NY (US)

(73) Assignee: Tokyo Electron Limited, Tokyo (JP)

(21) Appl. No.: 17/890,938

(22) Filed: Aug. 18, 2022

Related U.S. Application Data
(60) Provisional application No. 63/234,664, filed on Aug. 18, 2021.

(51) Int. Cl. H01L 29/417; H01L 29/06; H01L 29/786; H01L 21/8234; H01L 29/775; H01L 29/66

(52) U.S. Cl. CPC H01L 29/41783; H01L 21/823412; H01L 21/823418; H01L 29/0673; H01L 29/775; H01L 29/66439; H01L 29/78696

(57) ABSTRACT

A device structure is disclosed. The device structure includes a channel region having a first surface facing an underlying substrate and a second surface opposite to the first surface. The device structure includes a gate at least partially surrounding the channel region. The gate includes a gate dielectric and a gate conductor, in which the gate dielectric separates the gate conductor from the channel region. The device structure includes self-aligned source and drain regions (S/D regions) contacting the first and second surfaces, respectively.

### CROSS-REFERENCE TO RELATED APPLICATIONS

The present application claims the benefit of and priority to U.S. Provisional Pat. Application No. 63/234,664, filed Aug. 18, 2021, and entitled “Vertical Transistor Device,” the contents of which is incorporated by reference in its entirety for all purposes.

### TECHNICAL FIELD

This disclosure relates to non-planar, or three-dimensional (3D), structures and transistors. Channel regions of the disclosed transistor structures may be oriented to conduct current in a direction generally perpendicular to a major surface of the system or chip upon which, or within which, these structures are provided.

### BACKGROUND

Fabrication of semiconductor devices relies on execution of various fabrication processes that are performed repeatedly in order to form desired semiconductor features on a substrate. In the recent years, scaling down semiconductor devices became more challenging as features sizes reached single digit nanometer range.

### SUMMARY

In order to continue scaling down semiconductor devices, device structures can be designed to extend in their vertical direction, such as upwards from the substrate on which they are fabricated. The present disclosure provides three-dimensional (3D) semiconductor circuits in which transistor structures can be designed to extend in vertical direction, as well as be stacked on top of each other, thereby allowing for greater number of devices to be fabricated within a substrate surface area. For example, each transistor structure, as disclosed herein, includes a vertically oriented nanosheet functions as its (conduction) channel. Such a nanosheet can be epitaxially grown based on a stack formed over the substrate. By exposing at least a top surface and bottom surface of the nanosheet, source and drain regions can be simultaneously grown from the nanosheet. In this way, the conductive type of each transistor structure can be customized, and its source and drain regions can be self-aligned with its channel (e.g., nanosheet). Further, the stack can include a multiple number of such nanosheets, which allows a number of transistor structures to be stacked on top of one another, and the transistor structures can have either the same conductive type or different conductive types.

One aspect of the present disclosure is directed to a device structure. The device structure may include a channel region having a first surface facing an underlying substrate and a second surface opposite to the first surface; a gate at least partially surrounding the channel region, the gate including a gate dielectric and a gate conductor, the gate dielectric separating the gate conductor from the channel region; and self-aligned source and drain regions (S/D regions) contacting the first and second surfaces, respectively.

The device structure may further include source and drain electrodes (S/D electrodes) contacting the respective self-aligned S/D regions, the S/D electrodes vertically adjacent the gate dielectric. The S/D electrodes may surround the respective self-aligned S/D regions.

The channel region may comprise an undoped semiconductor material. The self-aligned S/D regions each comprise a doped semiconductor material. The gate conductor is formed as a ring structure, with its inner sidewall, top surface, and bottom surface being in contact with the gate dielectric of the gate.

The device structure may further include a second channel region having a third surface facing the underlying substrate and a fourth surface opposite to the third surface; a second gate at least partially surrounding the second channel region, the second gate including a second gate dielectric and a second gate conductor, the second gate dielectric separating the second gate conductor from the second channel region; and second self-aligned source and drain regions (S/D regions) contacting the third and fourth surfaces, respectively.

The first channel region and second channel region may each comprise an undoped semiconductor material. The first self-aligned S/D regions each comprise a first doped semiconductor material with a first conductive type, and the second self-aligned source and drain regions (S/D regions) each comprise a second doped semiconductor material with a second conductive type. The gate conductor has the first conductive type, and the second gate conductor has the second conductive type.

Another aspect of the present disclosure may be directed to a device structure. The device structure includes a first device comprising: a first channel region having a first surface facing an underlying substrate and a second surface opposite to the first surface; a first gate at least partially surrounding the first channel region, the first gate adjacent a third surface of the first channel region, the third surface extending between the first and second surfaces, the first gate including a first gate dielectric and a first gate conductor, the first gate dielectric separating the first gate conductor from the first channel region; and first self-aligned source and drain regions (S/D regions) contacting the first and second surfaces, respectively. The device structure includes a second device isolated from the first device and comprising: a second channel region having a fourth surface facing the underlying substrate and a fifth surface opposite to the fourth surface; a second gate at least partially surrounding the second channel region, the second gate adjacent a sixth surface of the second channel region, the sixth surface extending between the fourth and fifth surfaces, the second gate including a second gate dielectric and a second gate conductor, the second gate dielectric separating the second gate conductor from the second channel region; and second self-aligned source and drain regions (S/D regions) contacting the fourth and fifth surfaces, respectively.

The first and second devices have a same conductive type, or have respectively different conductive types. The first and second channel regions each comprise an undoped semiconductor material. The first and second self-aligned S/D regions each comprise a doped semiconductor material.

The first gate conductor may be formed as a first ring structure, with its inner sidewall, top surface, and bottom surface being in contact with the first gate dielectric, and wherein the second gate conductor of the gate is formed as a second ring structure, with its inner sidewall, top surface, and bottom surface being in contact with the second gate dielectric.

The first device may further comprise first source and drain electrodes (S/D electrodes) contacting the respective first self-aligned S/D regions, the first S/D electrodes vertically adjacent the first gate dielectric. The second device further comprises second source and drain electrodes (S/D electrodes) contacting the respective second self-aligned S/D regions, the second S/D electrodes vertically adjacent the second gate dielectric. The first S/D electrodes are above and below the first gate conductor, respectively, and the second S/D electrodes are above and below the second gate conductor, respectively.

Yet another aspect of the present disclosure may be directed to a method for fabricating semiconductor devices. The method includes forming a channel region over a substrate as one of a series of epitaxially-grown layers; forming source and drain regions (S/D regions) by epitaxially growing semiconductor layers on opposing sides of the channel region; and forming a gate at least partially surrounding the channel region, the gate comprising a gate conductor and a gate dielectric, the gate dielectric separating the gate conductor from the channel region.

The channel region may comprise an undoped semiconductor material.

The method may further include forming source and drain electrodes (S/D electrodes) contacting the respective S/D regions, the S/D electrodes vertically adjacent the gate dielectric.

The method may further include forming source and drain contacts at least partially surrounding respective source and drain regions, the gate dielectric separating the gate conductor from the source and drain contact

These and other aspects and implementations are discussed in detail below. The foregoing information and the following detailed description include illustrative examples of various aspects and implementations, and provide an overview or framework for understanding the nature and character of the claimed aspects and implementations. The drawings provide illustrations and a further understanding of the various aspects and implementations, and are incorporated in and constitute a part of this specification. Aspects can be combined, and it will be readily appreciated that features described in the context of one aspect of the invention can be combined with other aspects. Aspects can be implemented in any convenient form. As used in the specification and in the claims, the singular form of “a,” “an,” and “the” include plural referents unless the context clearly dictates otherwise.

### BRIEF DESCRIPTION OF THE DRAWINGS

Non-limiting embodiments of the present disclosure are described by way of example with reference to the accompanying figures, which are schematic and are not intended to be drawn to scale. Unless indicated as representing the background art, the figures represent aspects of the disclosure. For purposes of clarity, not every component may be labeled in every drawing. In the drawings:

FIG. 1 illustrates a flow chart of an example method for making a semiconductor device, in accordance with some embodiments.

FIGS. 2 to 18 illustrate respective cross-sectional or top views of a semiconductor device during various fabrication stages of the method of FIG. 1, in accordance with some embodiments.

FIG. 19 illustrates a flow chart of another example method for making a semiconductor device, in accordance with some embodiments.

FIGS. 20 to 39 illustrate respective cross-sectional or top views of a semiconductor device during various fabrication stages of the method of FIG. 19, in accordance with some embodiments.

### DETAILED DESCRIPTION

Reference will now be made to the illustrative embodiments depicted in the drawings, and specific language will be used here to describe the same. It will nevertheless be understood that no limitation of the scope of the claims or this disclosure is thereby intended. Alterations and further modifications of the inventive features illustrated herein, and additional applications of the principles of the subject matter illustrated herein, which would occur to one skilled in the relevant art and having possession of this disclosure, are to be considered within the scope of the subject matter disclosed herein. Other embodiments may be used and/or other changes may be made without departing from the spirit or scope of the present disclosure. The illustrative embodiments described in the detailed description are not meant to be limiting of the subject matter presented.

Likewise, although the Figures and aspects of the disclosure may show or describe devices herein as having a particular shape, it should be understood that such shapes are merely illustrative and should not be considered limiting to the scope of the techniques described herein. For example, although certain figures show various layers defining transistor structures or other electric structures in a circular configuration, other shapes are also contemplated, and indeed the techniques described herein may be implemented in any shape or geometry.

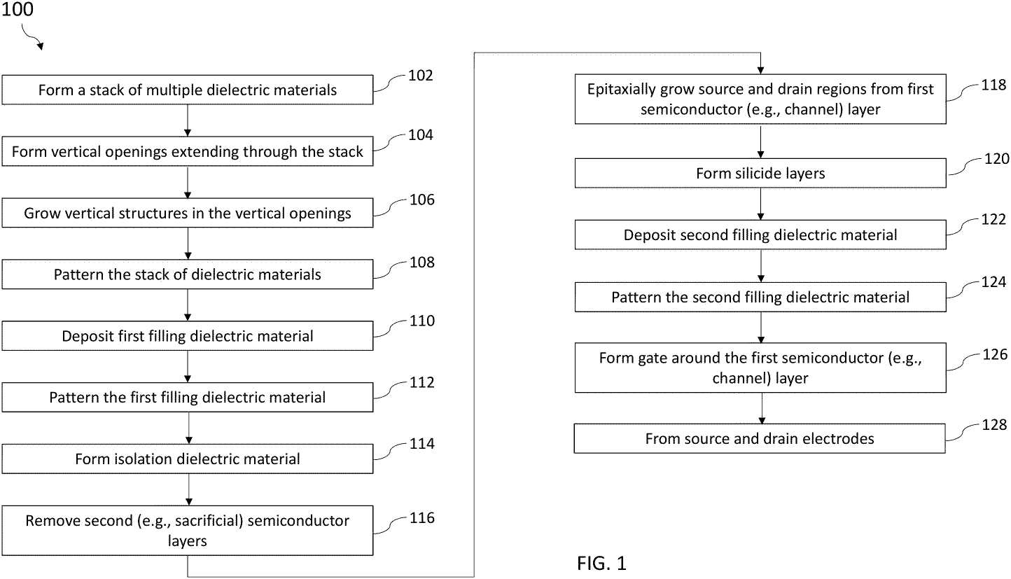

FIG. 1 illustrates a flowchart of an example method 100 for forming a semiconductor device (e.g., including one or more transistor structures) based on a vertical nanosheet. For example, each of the transistor structures may be a vertical transistor having its channel region (implemented as a nanosheet) extending along a vertical direction, its source/drain regions epitaxially grown from (and self-aligned with) the channel region along that vertical direction, and its gate surrounding the channel region. Further, through performing at least some of operations of the method 100, a number of these vertical transistors can be formed to stack on top of one another, and such stacked vertical transistors may have the same conductive type. It is noted that the method 100 is merely an example, and is not intended to limit the present disclosure. Accordingly, it is understood that additional operations may be provided before, during, and after the method 100 of FIG. 1, and that some other operations may only be briefly described herein.

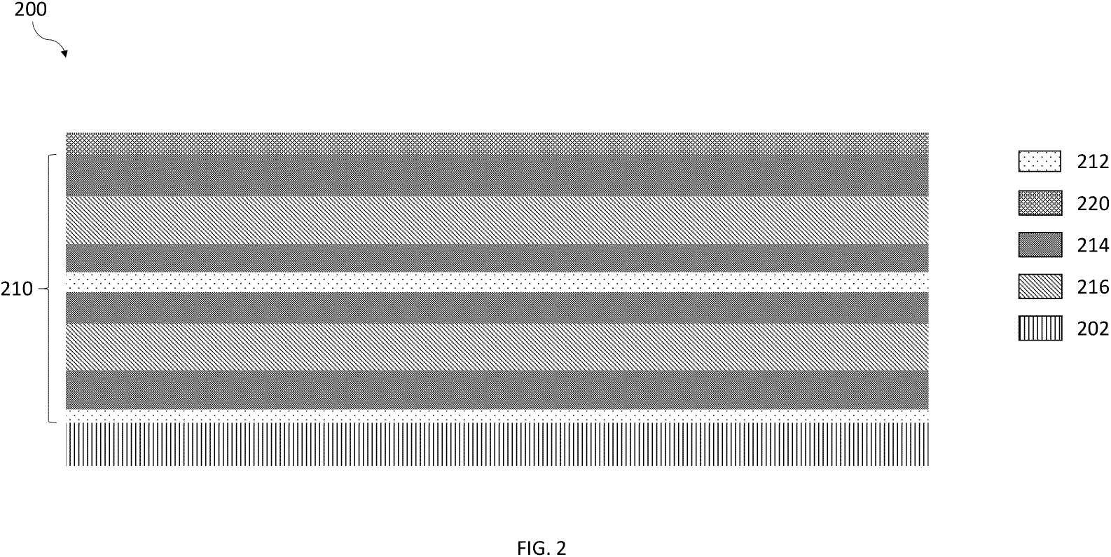

In various embodiments, operations of the method 100 may be associated with top views or cross-sectional views of an example semiconductor device 200 at various fabrication stages as shown in FIGS. 2 to 18, which will be discussed in further detail below. It should be understood that the semiconductor device 200, shown in FIGS. 2 to 18, may include a number of other devices such as inductors, fuses, capacitors, coils, etc., while remaining within the scope of the present disclosure.

In brief overview, the method 100 starts with operation 102 of forming a stack of multiple dielectric materials over a substrate. The method 100 continues to operation 104 of forming a number of vertical openings extending through the stack. The method 100 proceeds to operation 106 of epitaxially growing a number of vertical structures in the vertical openings. In various embodiments, the vertical structure can include at least one first semiconductor layer vertically interposed between a pair of second (e.g., sacrificial) semiconductor layers. The method 100 proceeds to operation 108 of forming further patterning the stack of dielectric materials. The method 100 proceeds to operation 110 of depositing a first filling dielectric material to fill the patterned stack. The method 100 proceeds to operation 112 of patterning the first filling dielectric material to expose a portion of each of the vertical structures. The method 100 proceeds to operation 114 of forming an isolation dielectric material to electrically isolate the vertical structures from the substrate. The method 100 proceeds to operation 116 of removing the second (e.g., sacrificial) semiconductor layers. The method 100 proceeds to operation 118 of epitaxially growing a source region and drain region from each of the first semiconductor layers. The method 100 proceeds to operation 120 of forming silicide layers on the source and drain regions, respectively. The method 100 proceeds to operation 122 of depositing a second filling dielectric material to at least partially fill up the vertical structures. The method 100 proceeds to operation 124 of patterning the second filling dielectric material to again expose the portion of each of the vertical structures. The method 100 proceeds to operation 126 of forming a gate around each of the first semiconductor layers. The method 100 proceeds to operation 128 of forming a number of source electrodes and a number of drain electrodes.

Corresponding to operation 102 of FIG. 1, FIG. 2 is a cross-sectional view of the semiconductor device 200 in which, over a substrate 202, a stack 210 including a number of first dielectric materials 212, a number of second dielectric materials 214, and a number of third dielectric materials 216 is formed, in accordance with various embodiments.

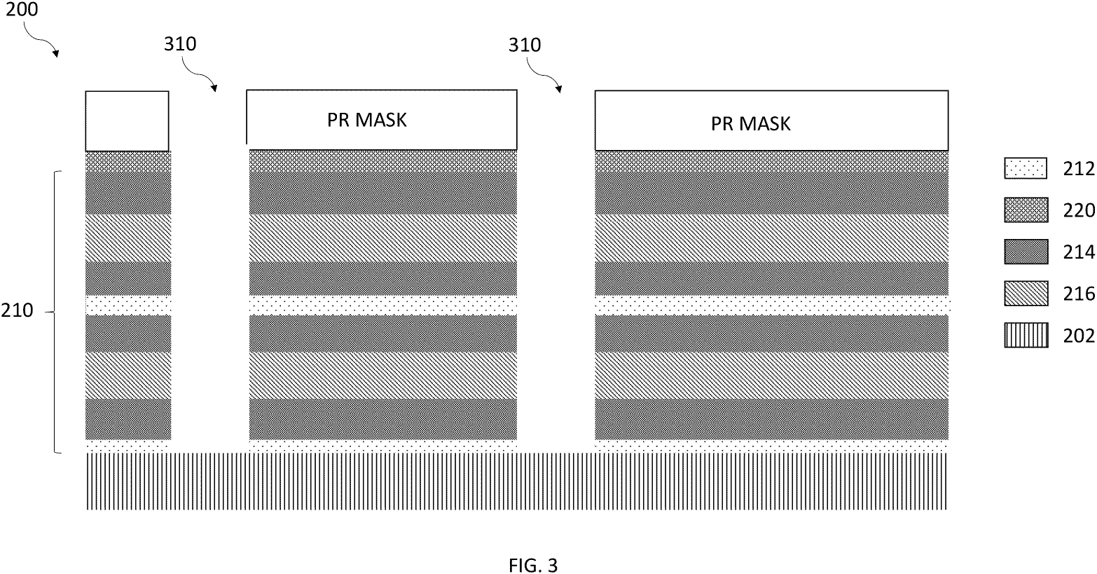

As shown, over the substrate 202, a first one of the first dielectric materials 212 is first formed, sequentially followed by a first one of the second dielectric materials 214, a first one of the third dielectric materials 216, and a second one of the second dielectric materials 214, which form a first (e.g., lower) portion of the stack. The stack 210 can include any number of such portions by repeating forming the first to third dielectric materials. For example in FIG. 2, the stack 210 includes a second (e.g., upper) portion, which includes a second one of the first dielectric materials 212, a third one of the second dielectric materials 214, a second one of the third dielectric materials 216, and a fourth one of the second dielectric materials 214. Over a topmost one of the dielectric materials of the stack 210 (e.g., the fourth second dielectric materials 214 in the example of FIG. 2), a hardmask layer 220 can be formed to facilitate the following patterning process (e.g., FIG. 3).

The substrate 202 includes a semiconductor material substrate, for example, silicon. Alternatively, the substrate 202 may include other elementary semiconductor material such as, for example, germanium. The substrate 202 may also include a compound semiconductor such as silicon carbide, gallium arsenic, indium arsenide, and indium phosphide. The substrate 202 may include an alloy semiconductor such as silicon germanium, silicon germanium carbide, gallium arsenic phosphide, and gallium indium phosphide. In one embodiment, the substrate 202 includes an epitaxial layer. For example, the substrate 202 may have an epitaxial layer overlying a bulk semiconductor. Furthermore, the substrate 202 may include a semiconductor-on-insulator (SOI) structure. For example, the substrate 202 may include a buried oxide (BOX) layer formed by a process such as separation by implanted oxygen (SIMOX) or other suitable technique, such as wafer bonding and grinding.

The first to third dielectric materials, 212, 214, and 216, may have different etching selectivities. For example, the third dielectric material 216 may have a different etching selectivity from the second dielectric material 214. As such, while the third dielectric material 216 is being etched, the second dielectric material 214 may remain substantially intact.

The first to third dielectric materials 212, 214, and 216, may each include at least one insulation material, which can electrically isolate neighboring active structures (e.g., metal electrodes which will be formed below) from each other. The insulation material may be an oxide, such as a silicon oxide, a nitride, the like, or combinations thereof, and may be formed by a high density plasma chemical vapor deposition (HDP-CVD), a flowable CVD (FCVD) (e.g., a CVD-based material deposition in a remote plasma system and post curing to make it convert to another material, such as an oxide), the like, or combinations thereof. Other insulation materials and/or other formation processes may be used. An anneal process may be performed once the insulation material is formed.

Corresponding to operation 104 of FIG. 1, FIG. 3 is a cross-sectional view of the semiconductor device 200 in which a number of vertical openings 310 are formed to extend through the stack 210, in accordance with various embodiments.

Following the formation of the hardmask layer 220, a patternable layer (e.g., a photoresist mask) with patterns is formed over the hardmask layer 220. Next, at least one dry etching or a wet etching process including, e.g., dilute hydrofluoric (DHF) acid, may be performed to etch the stack 210 until the substrate 202 is exposed so as to form the vertical openings 310. In various embodiments, a number of vertical structures, including a stack of semiconductor layers, may be formed in the vertical openings 310, respectively. Such vertical structures can form a number of stacked transistor structures. Thus, the vertical openings 310 can define respective footprints of a number of transistor stacks on the substrate 202. Further, the vertical openings 310 can be formed with any of various cross-section. For example, each of the vertical openings 310 can have a circular (e.g., elliptical) cross-section, which will be shown below.

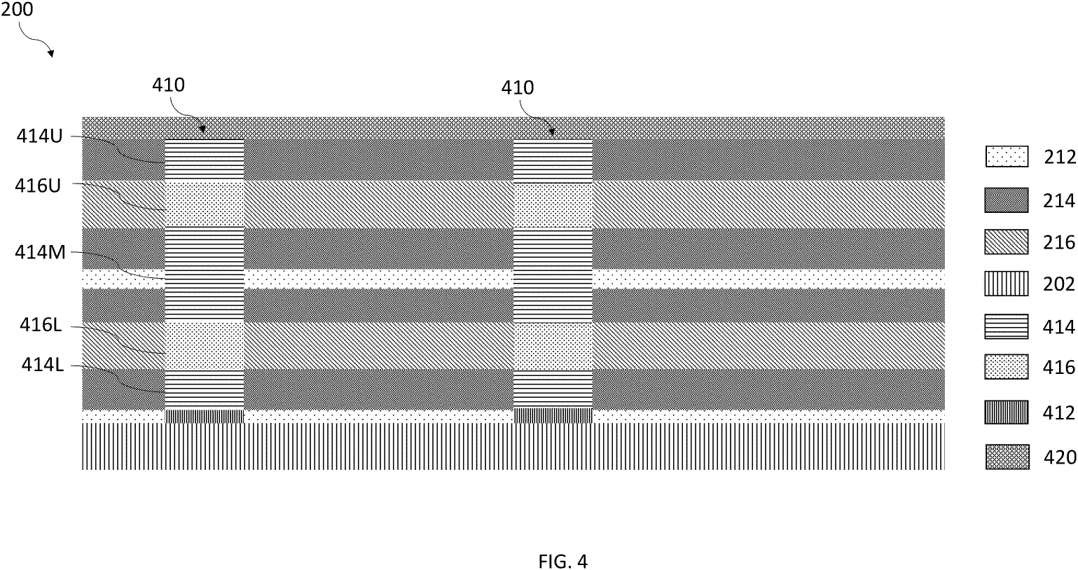

Corresponding to operation 106 of FIG. 1, FIG. 4 is a cross-sectional view of the semiconductor device 200 in which a number of vertical structures 410 are formed in the vertical openings 310, respectively, in accordance with various embodiments.

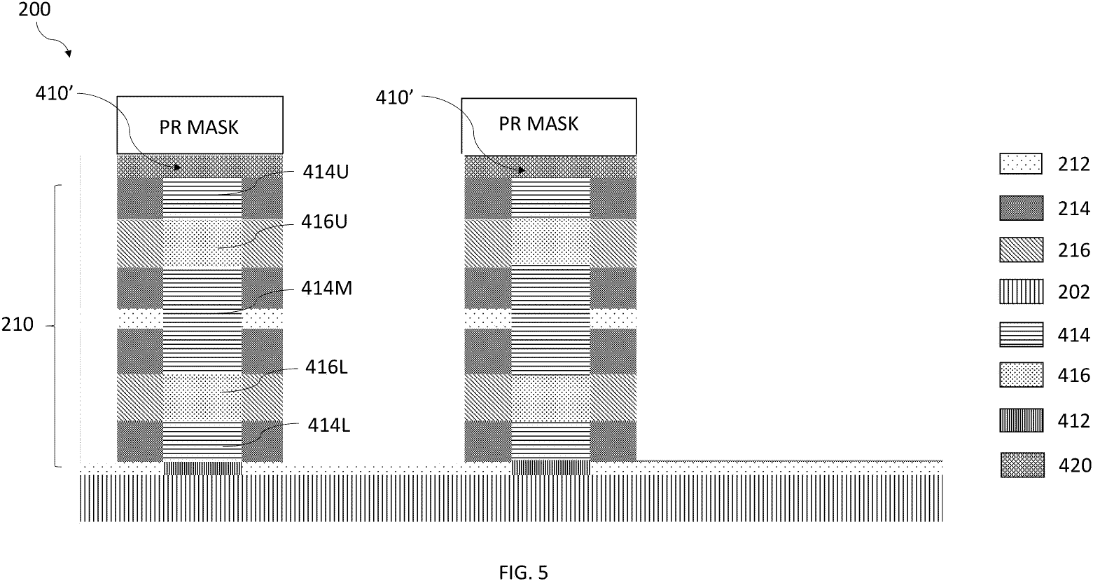

The vertical structures 410 can each include a number of epitaxially grown semiconductor layers 412, 414, and 416, in various embodiments. For example, the vertical structure 410 includes a first semiconductor layer 412 epitaxially grown from the substrate 202, a lower one of the second semiconductor layers 414 (414L) epitaxially grown from the first semiconductor layer 412, a lower one of the third semiconductor layers 416 (416L) epitaxially grown from the lower second semiconductor layer 414, a middle one of the second semiconductor layers 414 (414M) epitaxially grown from the lower third semiconductor layer 416, an upper one of the third semiconductor layers 416 (416U) epitaxially grown from the middle second semiconductor layer 414, and an upper one of the second semiconductor layers 414 (414U) epitaxially grown from the upper third semiconductor layer 416. Following the epitaxial growth of the upper second semiconductor layer 414, a hardmask layer 420 can be formed to facilitate the following patterning process (e.g., FIG. 5).

In various embodiments, the first to third semiconductor layers 412, 414, and 416, may have different etching selectivities. For example, the first semiconductor layer 412 may have a different etching selectivity from the second semiconductor layer 414, and the second semiconductor layer 414 may also have a different etching selectivity from the third semiconductor layer 416. As such, while the first semiconductor layer 412 is being etched, the second semiconductor layer 414 may remain substantially intact; and while the second semiconductor layer 414 is being etched, the third semiconductor layer 416 may remain substantially intact. In one implementation of the present disclosure, the first semiconductor layer 412 may include SiiₓGeₓ, the second semiconductor layer 414 may include Si₁-_{y}Ge_{y}, and the third semiconductor layer 416 may include Si or Ge, wherein the molar ratios x and y are different from each other. Further, the third semiconductor layers 416 may be intrinsic (i.e., without any dopants incorporated therein), in some embodiments.

In various embodiments, each of the third semiconductor layers 416 is vertically interposed between a pair of the second semiconductor layers 414. The third semiconductor layers 416 may each be configured as the channel (region) of a corresponding transistor structure, while the adjacent pair of second semiconductor layers 414 may be later removed or replaced with source/drain regions of the transistor structure, which will be discussed in further detail below. As such, the third semiconductor layer 416 and the second semiconductor layer 414 may sometimes be referred to as “channel layer/region 416” and “sacrificial layer 414,” respectively, in the following discussions. Based on such a rationale, the number of sandwiched channel layers 416 included in the stack 210 (e.g., 2 in the example of FIG. 2) may correspond to the number of transistor structures vertically stacked on top of one another.

Corresponding to operation 108 of FIG. 1, FIG. 5 is a cross-sectional view of the semiconductor device 200 in which the stack 210 is further patterned, in accordance with various embodiments.

Following the formation of the hardmask layer 420, a patternable layer (e.g., a photoresist mask) with patterns is formed over the hardmask layer 420. Next, at least one dry etching or a wet etching process including, e.g., dilute hydrofluoric (DHF) acid, may be performed to further etch the stack 210 until the bottommost first dielectric material 212 is exposed. Specifically, each of the vertical structures 410 can be surrounded by respectively remaining portions of the first dielectric material 212, the second dielectric materials 214, and the third dielectric materials 216. For example in the example of FIG. 5, the lower second semiconductor layer 414 (414L) is surrounded by a remaining portion of the second dielectric material 214, the lower third semiconductor layer 416 (416L) is surrounded by a remaining portion of the third dielectric material 216, and the middle second semiconductor layer 414 (414M) is surrounded collectively by the remaining portions of the second dielectric material 214 and first second dielectric material 212. Such a vertical structure 410 surrounded by the remaining dielectric materials is herein referred to as wrapped vertical structure 410'.

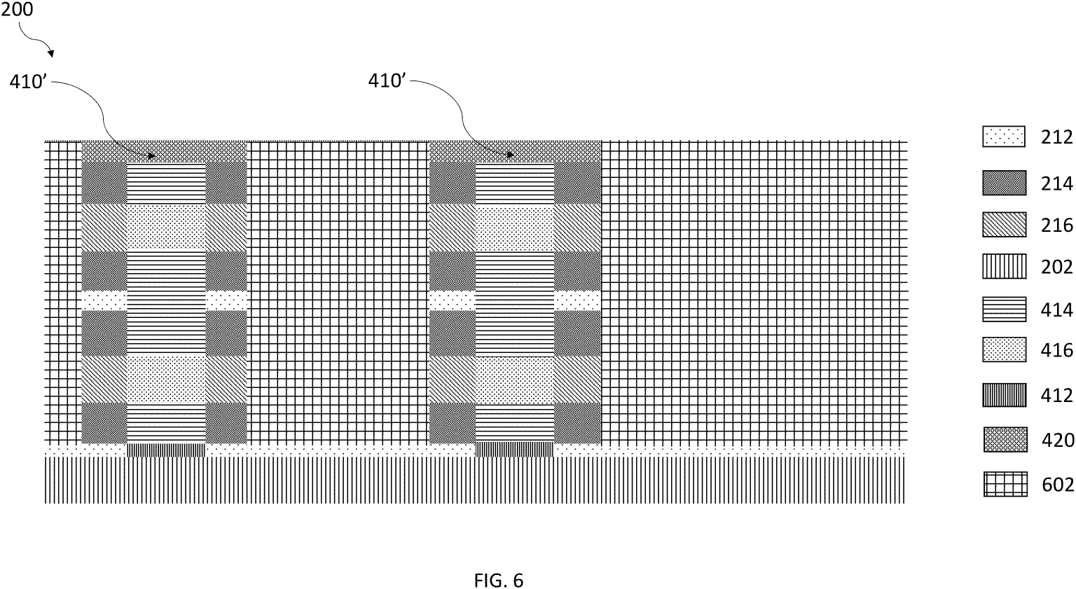

Corresponding to operation 110 of FIG. 1, FIG. 6 is a cross-sectional view of the semiconductor device 200 in which the patterned stack 210 is filled with a first filling dielectric material 602, in accordance with various embodiments.

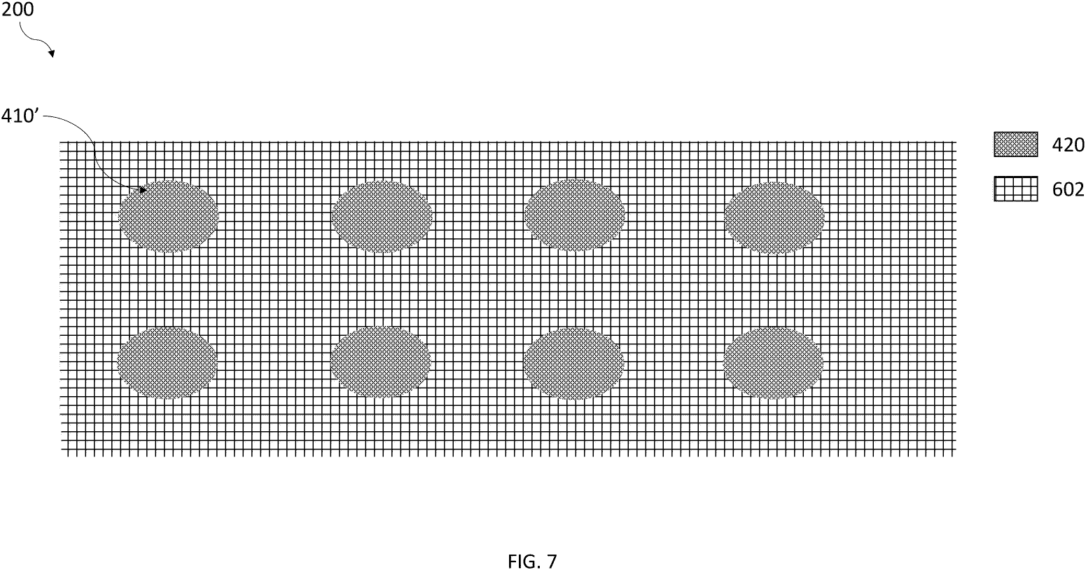

After removing the photoresist mask in FIG. 5, the first filling dielectric material 602 is deposited over the workpiece to fill up the patterned stack 210, followed by a chemical mechanical polishing (CMP) process. As such, the first filling dielectric material 602 can surround each of the wrapped vertical structures 410', as shown in the top view of FIG. 7.

The first filling dielectric material 602 includes at least one insulation material, which can electrically isolate neighboring active structures (e.g., metal electrodes which will be formed below) from each other. The insulation material may be an oxide, such as a silicon oxide, a nitride, the like, or combinations thereof, and may be formed by a high density plasma chemical vapor deposition (HDP-CVD), a flowable CVD (FCVD) (e.g., a CVD-based material deposition in a remote plasma system and post curing to make it convert to another material, such as an oxide), the like, or combinations thereof. Other insulation materials and/or other formation processes may be used. An anneal process may be performed once the insulation material is formed.

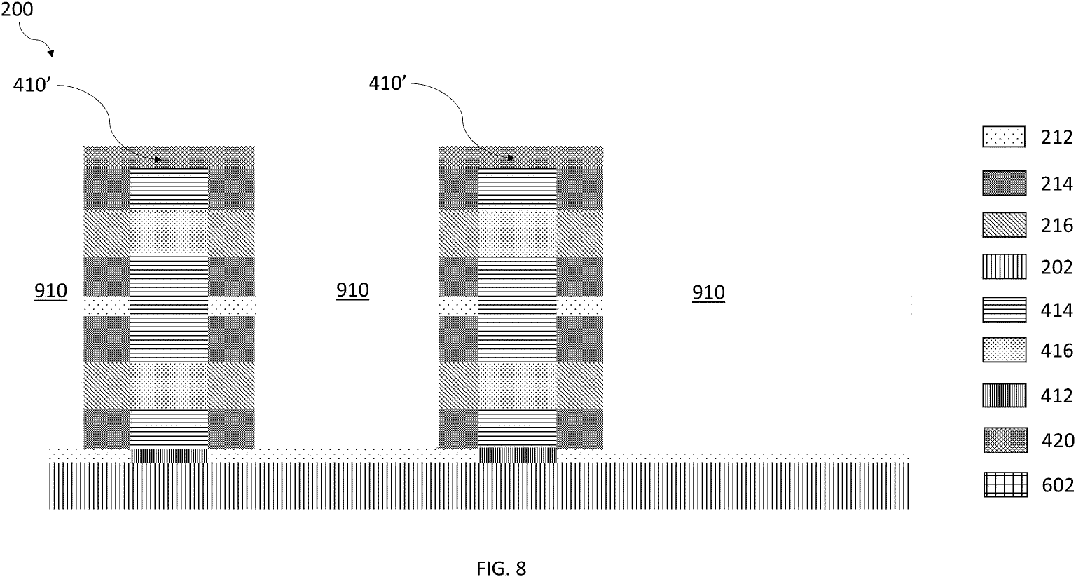

Corresponding to operation 112 of FIG. 1, FIG. 8 is a cross-sectional view of the semiconductor device 200 in which the first filling dielectric material 602 is patterned, thereby exposing a portion of each of the wrapped vertica', in accordance with various embodiments.

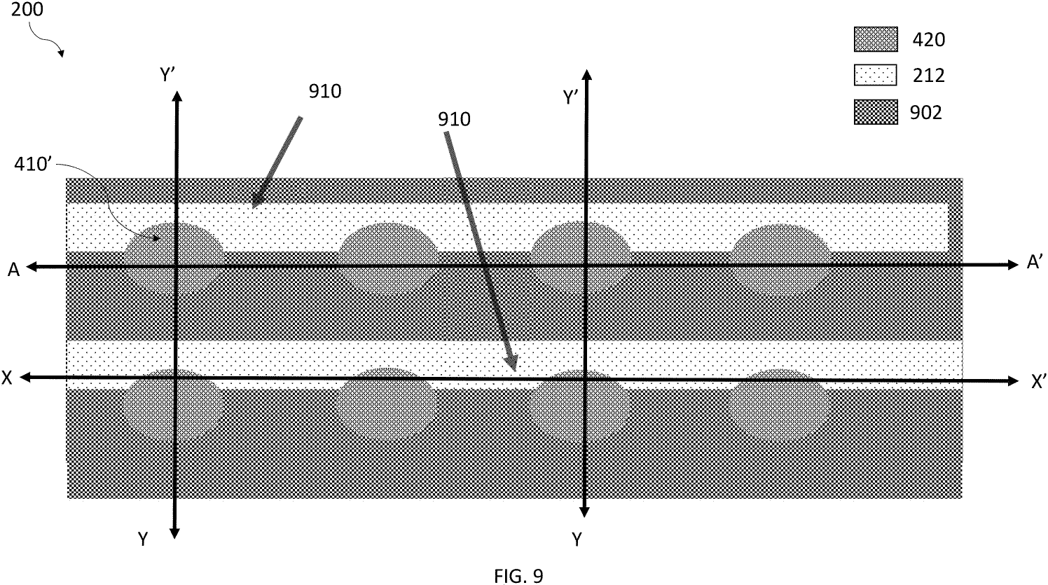

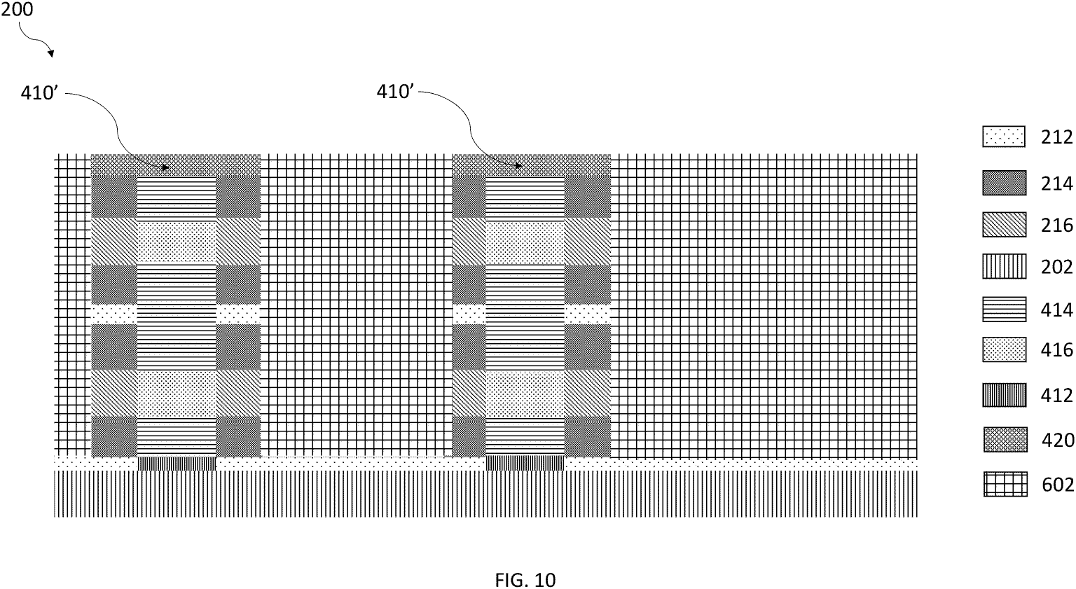

To illustrate the exposed portion of each of the wrapped vertical structures 410', a top view of the semiconductor device 200 is shown in FIG. 9. As illustrated, a patternable layer (e.g., a photoresist mask) 902 can be formed over the workpiece, e.g., with the hardmask layer 420 and first filling dielectric material 602 disposed therebelow. Further, the patternable layer 902 can have a pattern (e.g., one or more openings) exposing a portion of each of the wrapped vertical structures 410' and portions of the first filling dielectric material 602. By performing at least one etching process with the patternable layer 902 as a mask, one or more openings 910 can be formed, which can expose a portion of a sidewall of each of the wrapped vertical structures 410'. In FIG. 9, along cross-section X-X′, the corresponding portion of each of the wrapped vertical structures 410' is exposed by the opening 910 (as shown in the cross-sectional view of FIG. 8), while, along cross-section A-A′, the corresponding portion of each of the wrapped vertical structures 410' may still remain covered by the first filling dielectric material 602 (as shown in the cross-sectional view of FIG. 10).

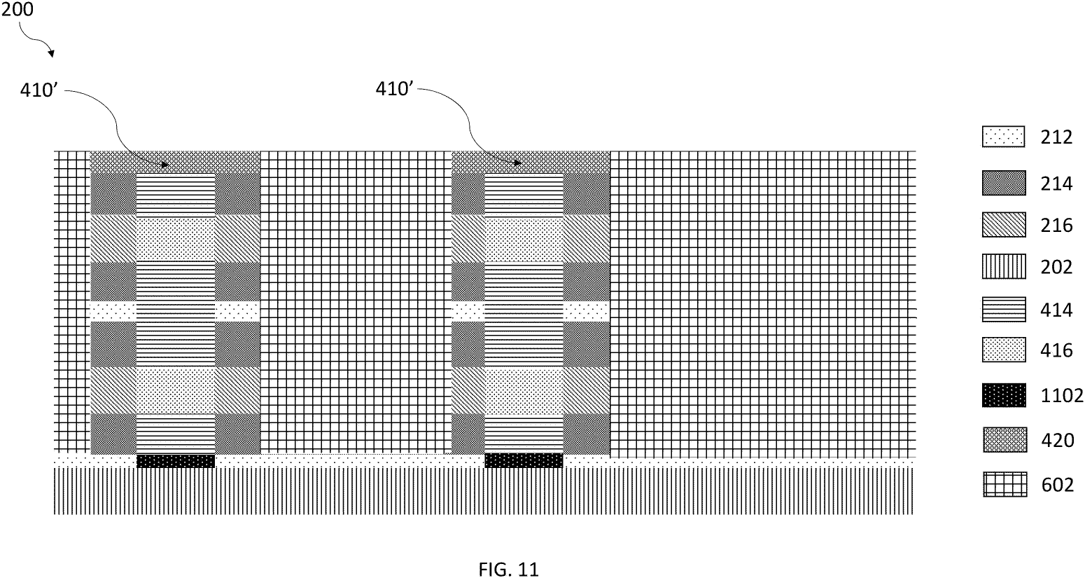

Corresponding to operation 114 of FIG. 1, FIG. 11 is a cross-sectional view of the semiconductor device 200 in which an isolation dielectric material 1102 is formed below each of the wrapped vertical structures 410', in accordance with various embodiments. It should be noted that the cross-sectional view of FIG. 11 is cut along cross-section A-A′, as illustrated in the top view of FIG. 9.

The isolation dielectric material 1102 is configured to electrically isolate the corresponding wrapped vertical structures 410' from the substrate 202. In some embodiments, the isolation dielectric material 1102 may be formed by performing at least some of the following processes: removing the patternable layer 902 (FIG. 9), removing the first semiconductor layers 412 to form cavities (beneath the wrapped vertical structures 410'), filling the cavities with an insulation material (through the openings 910 shown in FIG. 9) to form the isolation dielectric material 1102. The insulation material may be an oxide, such as a silicon oxide, a nitride, the like, or combinations thereof, and may be formed by a high density plasma chemical vapor deposition (HDP-CVD), a flowable CVD (FCVD) (e.g., a CVD-based material deposition in a remote plasma system and post curing to make it convert to another material, such as an oxide), the like, or combinations thereof. Other insulation materials and/or other formation processes may be used. Following the deposition of the insulation material, an etching process may be performed to remove excessive insulation material.

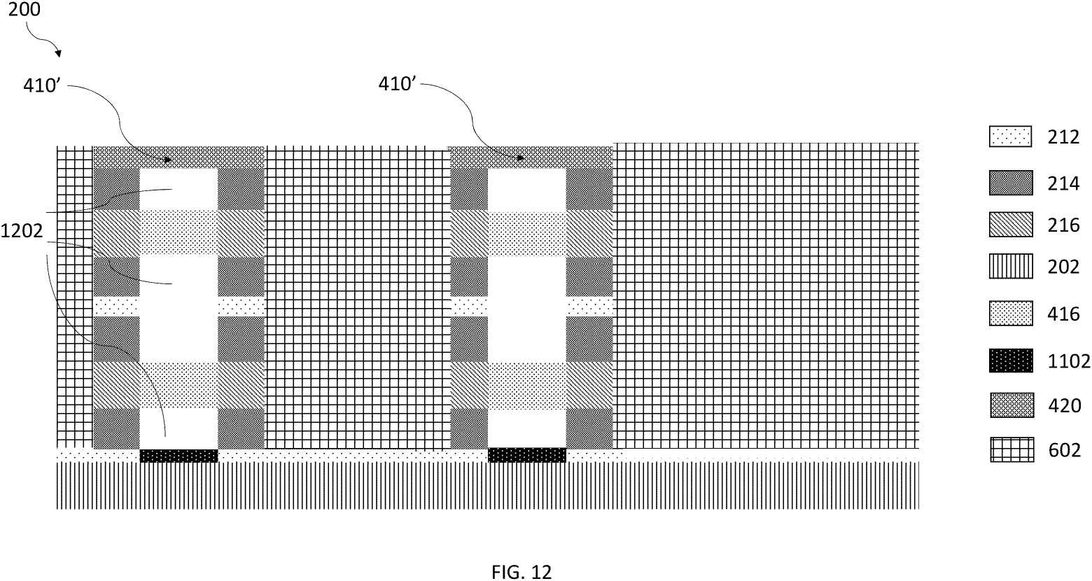

Corresponding to operation 116 of FIG. 1, FIG. 12 is a cross-sectional view of the semiconductor device 200 in which the second semiconductor layers 414 are removed, in accordance with various embodiments. It should be noted that the cross-sectional view of FIG. 12 is cut along cross-section A-A′, as illustrated in the top view of FIG. 9.

The second semiconductor layers 414 may be removed by a selective etching process, which leaves the third semiconductor layers 416 substantially intact. As such, a top surface and bottom surface of each of the third semiconductor layers 416 are exposed by cavities 1202, respectively, while a sidewall of each of the third semiconductor layers 416 may remain surrounded by the third dielectric material 216. Stated another way, upon removing the second semiconductor layers 414, each of the wrapped vertical structures 410' can include a number of cavities 1202 corresponding to the number of second semiconductor layers 414 included in the wrapped vertical structure 410'. The exposed top and bottom surfaces may be utilized to epitaxially grow source and drain regions, respectively, and the covering third dielectric material 216 may be replaced with a gate (structure), which will be discussed in further detail below.

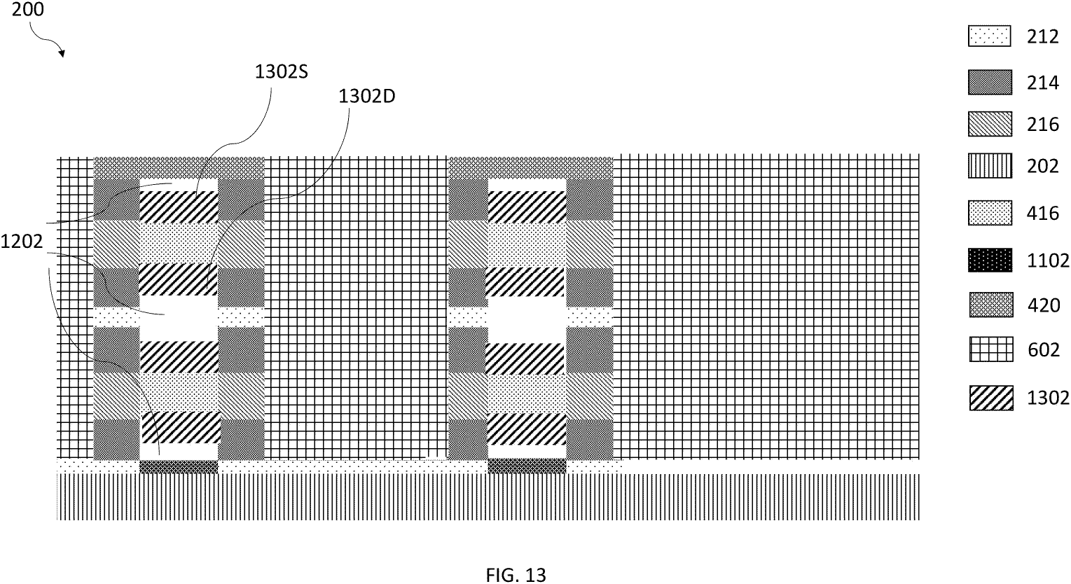

Corresponding to operation 118 of FIG. 1, FIG. 13 is a cross-sectional view of the semiconductor device 200 in which a number of self-aligned source/drain regions 1302 are formed, in accordance with various embodiments. It should be noted that the cross-sectional view of FIG. 13 is cut along cross-section A-A′, as illustrated in the top view of FIG. 9.

After forming the cavities 1202, the source/drain regions 1302 can formed by epitaxially growing a semiconductor material from the exposed third semiconductor layers 416. Specifically, the source/drain regions 1302 can be grown from the top and bottom surfaces of each of the third semiconductor layers 416. As such, each of the third semiconductor layers 416 may be vertically sandwiched by a pair of the source/drain regions 1302, one of which may operatively serve as a source region 1302S and the other of which may operatively serve as a drain region 1302D, as shown in the cross-sectional view of FIG. 13. The growth process includes any of the following suitable methods such as metal-organic CVD (MOCVD), molecular beam epitaxy (MBE), liquid phase epitaxy (LPE), vapor phase epitaxy (VPE), selective epitaxial growth (SEG), the like, or a combination thereof.

In various embodiments, the source/drain regions 1302 may be implanted with dopants to form doped source/drain regions 1302 followed by an annealing process. For example, when the resulting transistor structure is an n-type transistor, the doped source/drain regions 1302 can include silicon carbide (SiC), silicon phosphorous (SiP), phosphorous-doped silicon carbon (SiCP), or the like. When the resulting transistor structure is a p-type transistor, the source/drain regions 1302 can include SiGe, and a p-type impurity such as boron or indium. In some embodiments, the source/drain regions 1302 may be in situ doped during their growth.

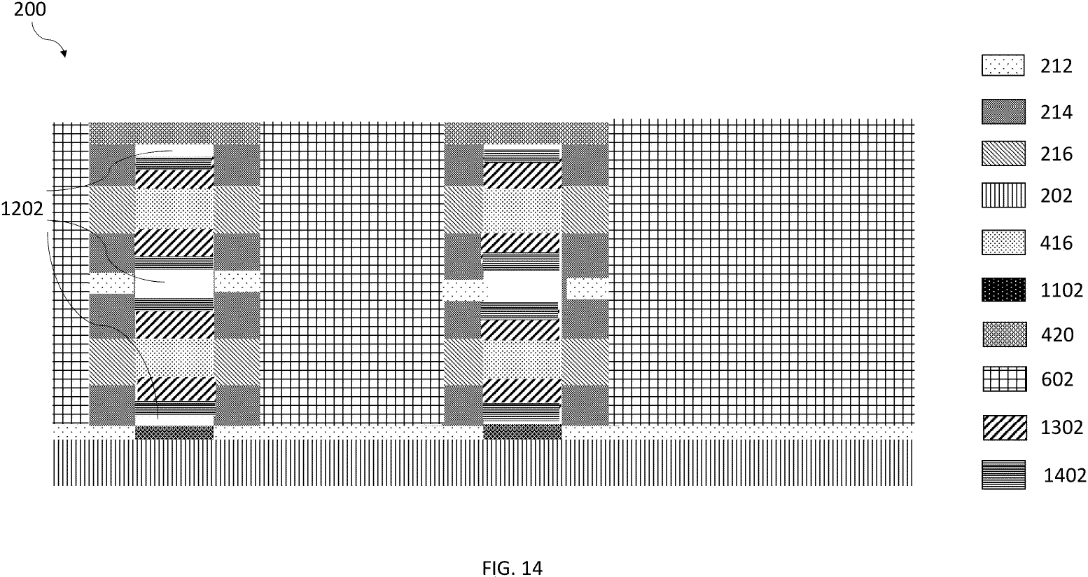

Corresponding to operation 120 of FIG. 1, FIG. 14 is a cross-sectional view of the semiconductor device 200 in which a number of silicide layers 1402 are formed, in accordance with various embodiments. It should be noted that the cross-sectional view of FIG. 14 is cut along cross-section A-A′, as illustrated in the top view of FIG. 9.

Each of the silicide layers 1402 can be formed at or near the exposed surface of a corresponding one of the source/drain regions 1302. As such, each of the third semiconductor layers 416 may be vertically sandwiched further by a pair of the silicide layers 1402. In some embodiments, after forming the silicide layers 1402, the cavities 1202 may still remain, as shown in FIG. 14. The silicide layers 1402 can include chemical compounds that can be formed within, between or near a semiconductor material, such as the third semiconductor layers 416, and a metal. For example, the silicide layer 1402 can be formed when a layer of metal that is suitable for forming a binary compound with silicon upon annealing, is in a physical contact with Si material and is exposed to a temperature level sufficiently high (e.g., in an annealing process) to form the silicide region at or near the interface of the Si and the metal.

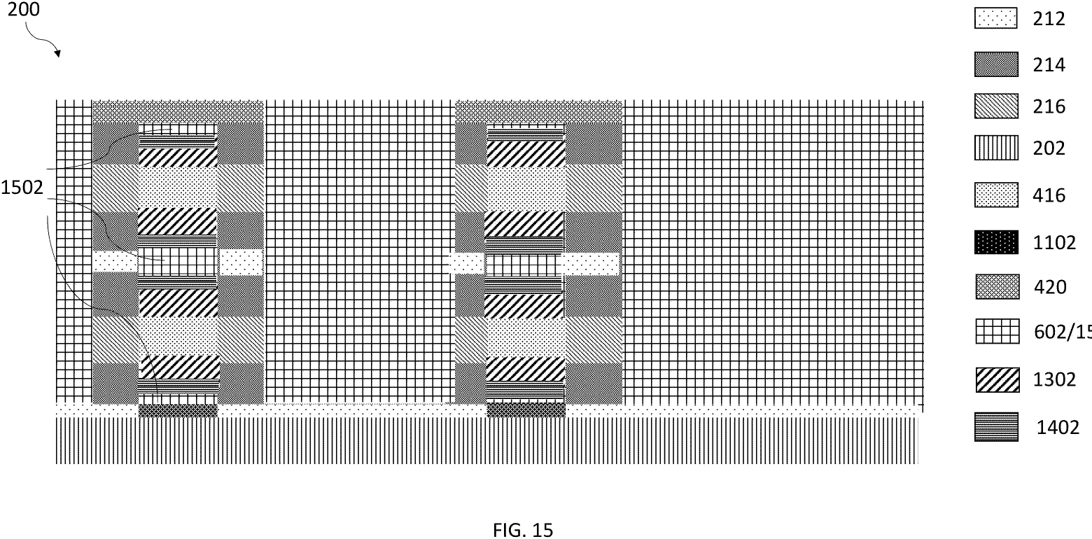

Corresponding to operation 122 of FIG. 1, FIG. 15 is a cross-sectional view of the semiconductor device 200 in which the cavities 1202 are each filled with a second filling dielectric material 1502, in accordance with various embodiments. It should be noted that the cross-sectional view of FIG. 15 is cut along cross-section A-A′, as illustrated in the top view of FIG. 9.

The cavities 1202 may each be fully filled with the second filling dielectric material 1502, as shown in FIG. 15. However, it should be understood that the cavities 1202 may each be partially filled with the second filling dielectric material 1502, while remaining within the scope of the present disclosure. As such, the wrapped vertical structure 410' can include one or more air gaps therein. In some embodiments, the second filling dielectric material 1502 is substantially similar to the first filling dielectric material 602. Accordingly, the second filling dielectric material 1502 includes at least one insulation material, which may be an oxide, such as a silicon oxide, a nitride, the like, or combinations thereof, and may be formed by a high density plasma chemical vapor deposition (HDP-CVD), a flowable CVD (FCVD) (e.g., a CVD-based material deposition in a remote plasma system and post curing to make it convert to another material, such as an oxide), the like, or combinations thereof. After the deposition of the second filling dielectric material 1502, a CMP process may be performed.

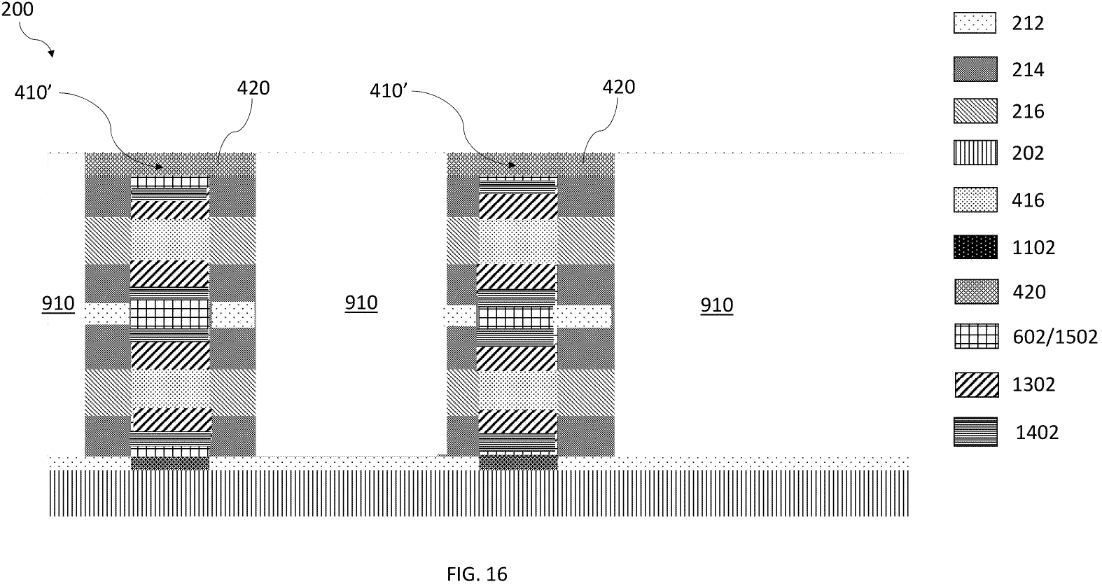

Corresponding to operation 124 of FIG. 1, FIG. 16 is a cross-sectional view of the semiconductor device 200 in which the openings 910 (FIG. 9) are exposed again, in accordance with various embodiments. It should be noted that the cross-sectional view of FIG. 16 is cut along cross-section X-X′, as illustrated in the top view of FIG. 9. In various embodiments, the openings 910 may be again exposed by etching at least the second filling dielectric material 1502, with the hardmask layer 420 functioning as a mask.

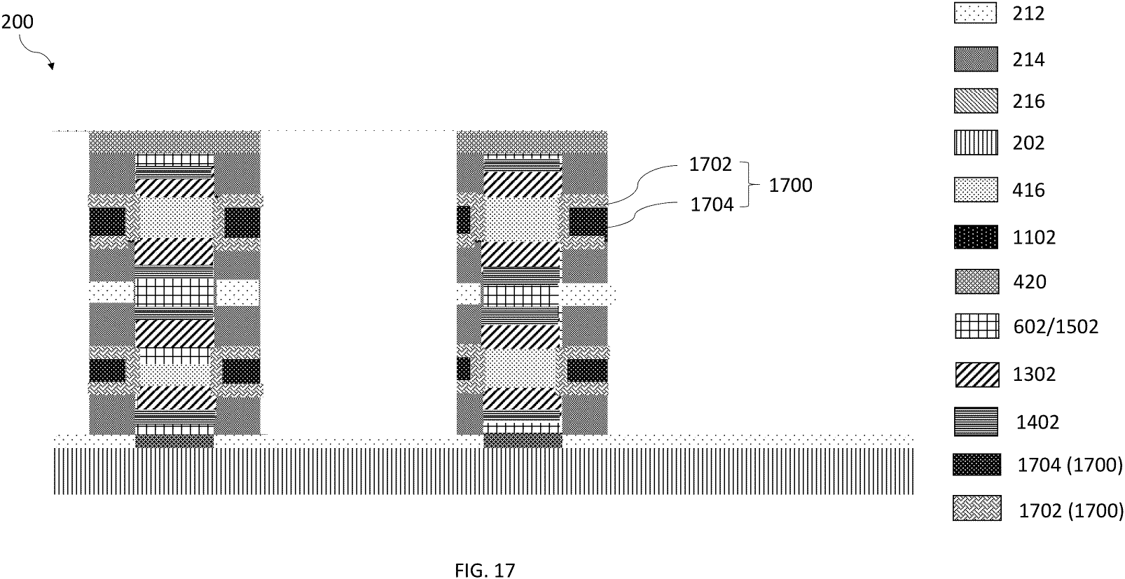

Corresponding to operation 126 of FIG. 1, FIG. 17 is a cross-sectional view of the semiconductor device 200 including a number of gates 1700, in accordance with various embodiments. It should be noted that the cross-sectional view of FIG. 17 is cut along cross-section X-X′, as illustrated in the top view of FIG. 9.

Upon re-exposing the openings 910, each of the third dielectric materials 216 surrounding a corresponding one of the third semiconductor layers 416 is removed. Next, a gate dielectric 1702 and a gate conductor 1704 are sequentially formed. In some embodiments, the gate dielectric 1702 and gate conductor 1704 are sometimes collectively referred to as a gate 1700. As the gates 1700 each replace a corresponding third dielectric material 216, the gate 1700 can inherit the dimensions and profiles of the corresponding third dielectric material 216, which allows the gate 1700 to wrap around a corresponding third semiconductor layer (channel layer/region) 416. Specifically in the cross-sectional view of FIG. 17, in addition to extending along (surrounding) sidewalls of the corresponding third semiconductor layer (channel layer/region) 416 with a vertical portion, the gate dielectric 1702 may have plural lateral portions disposed along a bottom surface of the above second dielectric material 214 and along a top surface of the below second dielectric materials 214, respectively. The gate conductor 1704, formed as a ring structure (when viewed from the top), can be vertically disposed between such lateral portions of the corresponding gate dielectric 1702.

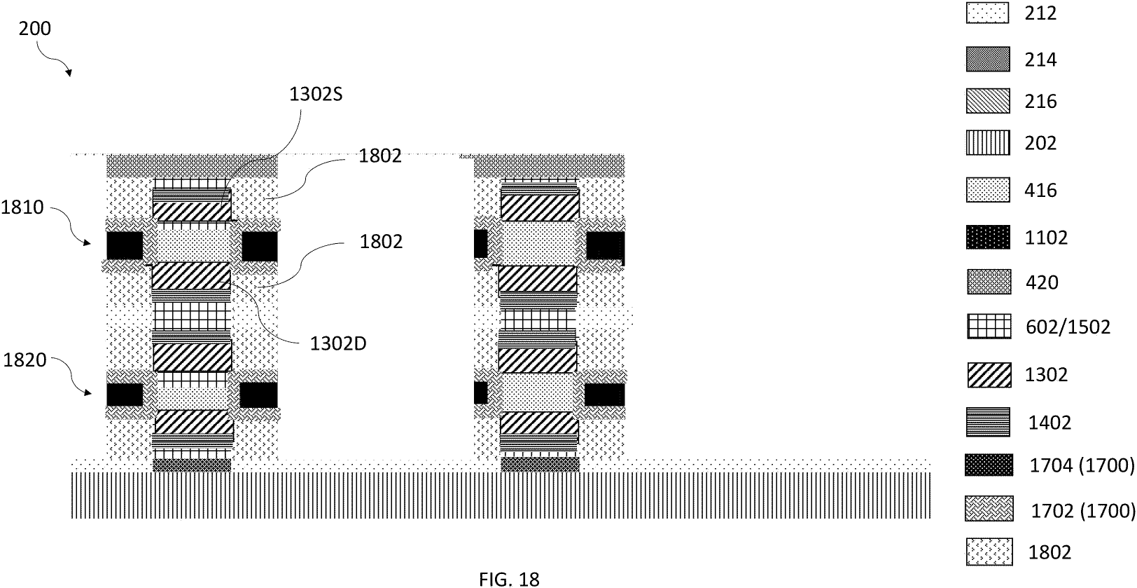

Corresponding to operation 128 of FIG. 1, FIG. 18 is a cross-sectional view of the semiconductor device 200 including a number of source/drain electrodes 1802, in accordance with various embodiments. It should be noted that the cross-sectional view of FIG. 18 is cut along cross-section X-X′, as illustrated in the top view of FIG. 9.

Upon forming the gates 1700, each of the second dielectric materials 214 surrounding a corresponding one of the source/drain regions 1302 is removed. Next, the source/drain electrodes 1802 are formed. As the source/drain electrodes 1802 each replace a corresponding second dielectric material 214, the source/drain electrode 1802 can inherit the dimensions and profiles of the corresponding second dielectric material 214, which allows the source/drain electrode 1802 to wrap around a corresponding source/drain region 1302. Specifically, the source/drain electrode 1802, formed as a ring structure (when viewed from the top), can be vertically disposed below or above the corresponding gate 1700.

In various embodiments, through performing at least some of the operations of the method 100, a number of vertical transistors stacked on top of one another can be formed. For example in FIG. 18, a first transistor 1810 and a second transistor 1820 are formed over the substrate 202. Each of the first transistor 1810 and second transistor 1820 has a corresponding third semiconductor layer 416 (functioning as channel), a corresponding gate 1700 surrounding the channel, and a pair of source/drain regions 1302 disposed above and below the channel, respectively. As the respective pairs of source/drain regions 1302 of the first transistor 1810 and second transistor 1820 are formed (e.g., doped) concurrently while the channel are formed as intrinsic, the first transistor 1810 and second transistor 1820 may have the same conductive type.

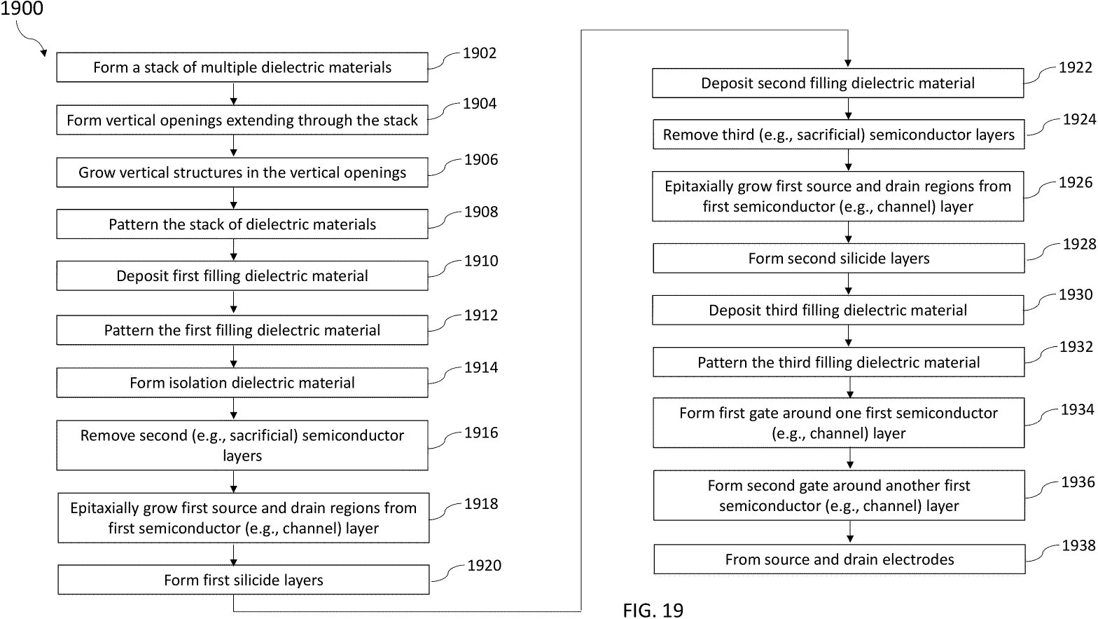

FIG. 19 illustrates a flowchart of an example method 1900 for forming a semiconductor device (e.g., including one or more transistor structures) based on a vertical nanosheet. For example, each of the transistor structures may be a vertical transistor having its channel region (implemented as a nanosheet) extending along a vertical direction, its source/drain regions epitaxially grown from (and self-aligned with) the channel region along that vertical direction, and its gate surrounding the channel region. Further, through performing at least some of operations of the method 1900, a number of these vertical transistors can be formed to stack on top of one another, and such stacked vertical transistors may have respectively different conductive types. It is noted that the method 1900 is merely an example and is not intended to limit the present disclosure. Accordingly, it is understood that additional operations may be provided before, during, and after the method 1900 of FIG. 19, and that some other operations may only be briefly described herein.

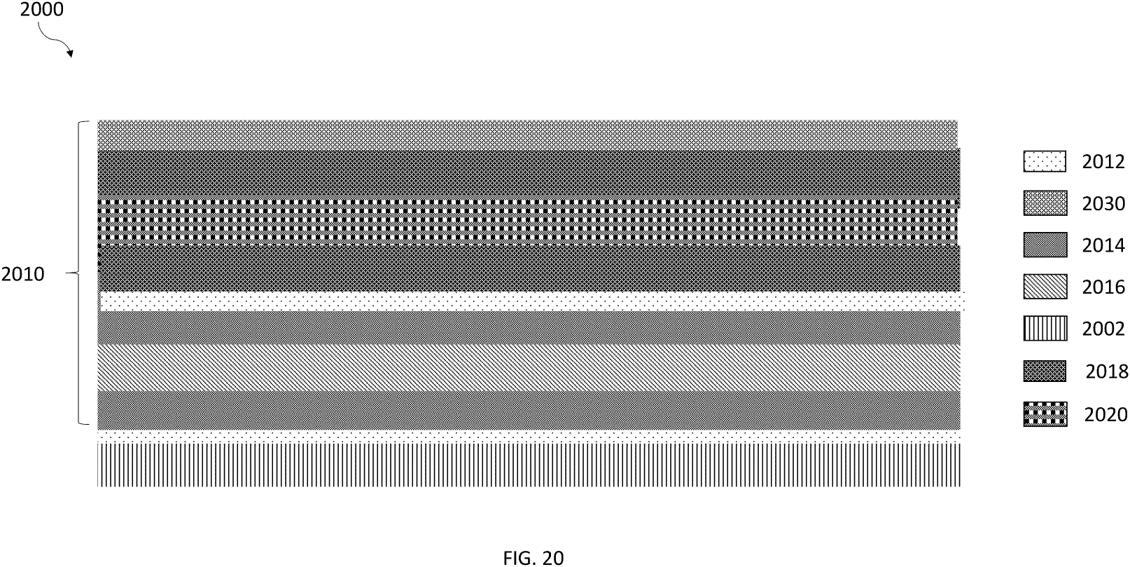

In various embodiments, operations of the method 1900 may be associated with top views and cross-sectional views of an example semiconductor device 2000 at various fabrication stages as shown in FIGS. 20 to 39, respectively, which will be discussed in further detail below. It should be understood that the semiconductor device 2000, shown in FIGS. 20 to 39, may include a number of other devices such as inductors, fuses, capacitors, coils, etc., while remaining within the scope of the present disclosure.

In brief overview, the method 1900 starts with operation 1902 of forming a stack of multiple dielectric materials over a substrate. The method 1900 continues to operation 1904 of forming a number of vertical openings extending through the stack. The method 1900 proceeds to operation 1906 of epitaxially growing a number of vertical structures in the vertical openings. In various embodiments, the vertical structure can include at least one first semiconductor layer vertically interposed between a pair of second (e.g., sacrificial) semiconductor layers, and at least another first semiconductor layer vertically interposed between a pair of third (e.g., sacrificial) semiconductor layers. The method 1900 proceeds to operation 1908 of forming further patterning the stack of dielectric materials. The method 1900 proceeds to operation 1910 of depositing a first filling dielectric material to fill up the patterned stack. The method 1900 proceeds to operation 1912 of patterning the first filling dielectric material to expose a portion of each of the vertical structures. The method 1900 proceeds to operation 1914 of forming an isolation dielectric material to electrically isolate the vertical structures from the substrate. The method 1900 proceeds to operation 1916 of removing the second (e.g., sacrificial) semiconductor layers. The method 1900 proceeds to operation 1918 of epitaxially growing a first source region and first drain region from one of the first semiconductor layers. The method 1900 proceeds to operation 1920 of forming first silicide layers on the first source and first drain regions, respectively. The method 1900 proceeds to operation 1922 of depositing a second filling dielectric material to at least partially fill up the vertical structures. The method 1900 proceeds to operation 1924 of removing the third (e.g., sacrificial) semiconductor layers. The method 1900 proceeds to operation 1926 of epitaxially growing a second source region and second drain region from another of the first semiconductor layers. The method 1900 proceeds to operation 1928 of forming second silicide layers on the second source and second drain regions, respectively. The method 1900 proceeds to operation 1930 of depositing a third filling dielectric material to at least partially fill up the vertical structures. The method 1900 proceeds to operation 1932 of patterning the third filling dielectric material to again expose the portion of each of the vertical structures. The method 1900 proceeds to operation 1934 of forming a first gate around one of the first semiconductor layers. The method 1900 proceeds to operation 1936 of forming a second gate around another of the first semiconductor layers. The method 1900 proceeds to operation 1938 of forming a number of source electrodes and a number of drain electrodes.

In various embodiments, most of the operations of the method 1900 are substantially similar to the operations of the method 100, except for the operation 1906 of forming at least one (e.g., lower) first semiconductor layer, vertically interposed between a pair of second (e.g., sacrificial) semiconductor layers, and another (e.g., upper) first semiconductor layer, vertically interposed between a pair of third (e.g., sacrificial) semiconductor layers. With these two first semiconductor layers sandwiched between different pairs of sacrificial semiconductor layers, respective pairs of source/drain regions can be separately formed for the upper and lower first semiconductor layers, e.g., the operations 1924, 1926, 1928, etc. Accordingly, the following cross-sectional views of the semiconductor device 2000 will be focused on the difference with respect to the semiconductor device 200.

Corresponding to operation 1902 of FIG. 19, FIG. 20 is a cross-sectional view of the semiconductor device 2000 in which, over a substrate 2002, a stack 2010 including a number of first dielectric materials 2012, a number of second dielectric materials 2014, a number of third dielectric materials 2016, a number of fourth dielectric materials 2018, and a number of fifth dielectric materials 2020 is formed, in accordance with various embodiments.

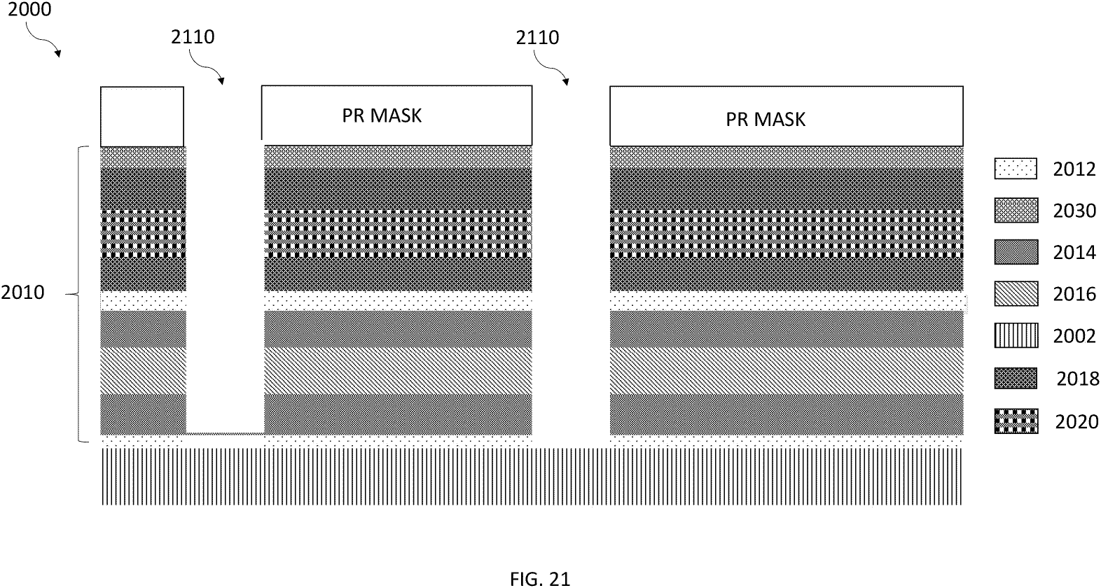

As shown, over the substrate 2002, a first one of the first dielectric materials 2012 is first formed, sequentially followed by a first one of the second dielectric materials 2014, the third dielectric material 2016, and a second one of the second dielectric materials 2014, which form a first (e.g., lower) portion of the stack. The stack 2010 can include any number of such portions by forming the fourth and fifth dielectric materials over another first dielectric material. For example in FIG. 20, the stack 2010 includes a second (e.g., upper) portion, which includes a second one of the first dielectric materials 2012, a first one of the fourth dielectric materials 2018, the fifth dielectric material 2020, and a second one of the fourth dielectric materials 2018. Over a topmost one of the dielectric materials of the stack 2010, a hardmask layer 2030 can be formed to facilitate the following patterning process (e.g., FIG. 21). The first to fifth dielectric materials, 2012, 2014, 2016, 2018, and 2020, may have different etching selectivities.

Corresponding to operation 1904 of FIG. 19, FIG. 21 is a cross-sectional view of the semiconductor device 2000 in which a number of vertical openings 2110 are formed to extend through the stack 2010, in accordance with various embodiments.

Following the formation of the hardmask layer 2030, a patternable layer (e.g., a photoresist mask) with patterns is formed over the hardmask layer 20300. Next, at least one dry etching or a wet etching process including, e.g., dilute hydrofluoric (DHF) acid, may be performed to etch the stack 2010 until the substrate 2002 is exposed so as to form the vertical openings 2110. In various embodiments, a number of vertical structures, including a stack of semiconductor layers, may be formed in the vertical openings 2110, respectively. Such vertical structures can form a number of stacked transistor structures. Thus, the vertical openings 2110 can define respective footprints of a number of transistor stacks on the substrate 2002. Further, the vertical openings 2110 can be formed with any of various cross-section.

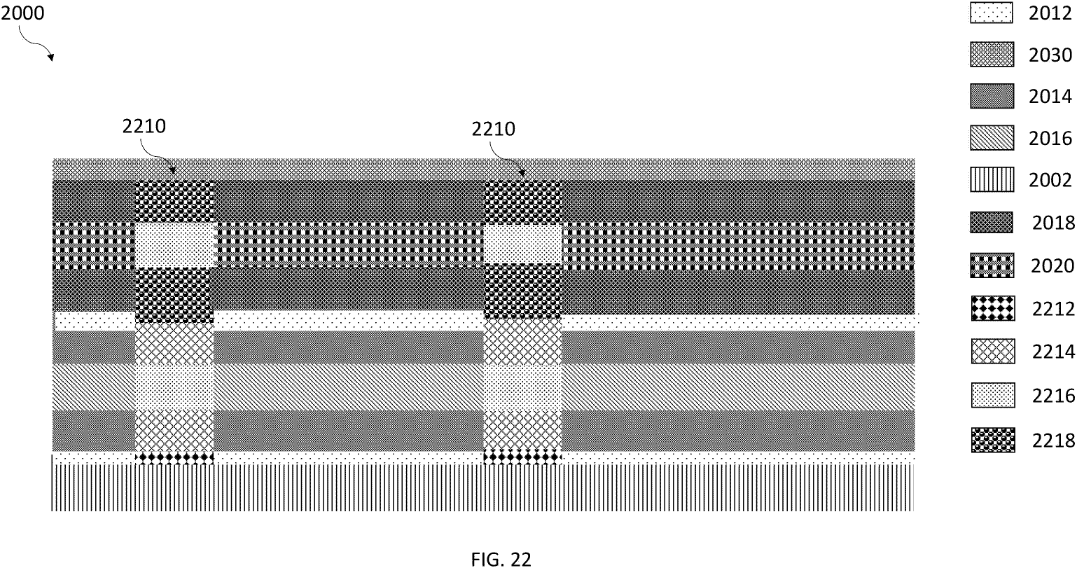

Corresponding to operation 1906 of FIG. 19, FIG. 22 is a cross-sectional view of the semiconductor device 2000 in which a number of vertical structures 2210 are formed in the vertical openings 2110, respectively, in accordance with various embodiments.

The vertical structures 2210 can each include a number of epitaxially grown first, second, third, and fourth semiconductor layers, 2212, 2214, 2216, and 2218, in various embodiments. In various embodiments, the first to fourth semiconductor layers 2212, 2214, 2216, and 2218, may have different etching selectivities. In one implementation of the present disclosure, the first semiconductor layer 2212 may include Si₁-ₓGeₓ, the second semiconductor layer 2214 may include Si₁-_{y}Ge_{y}, the third semiconductor layer 2216 may include Si or Ge, and the fourth semiconductor layer 2218 may include Si₁-_{z}Ge_{z}, wherein the molar ratios x, y, and z are different from each other. Further, the third semiconductor layers 2216 may be intrinsic (i.e., without any dopants incorporated therein), in some embodiments.

In various embodiments, the lower third semiconductor layer 2216 is vertically interposed between a pair of the second semiconductor layers 2214, and the upper third semiconductor layer 2216 is vertically interposed between a pair of the fourth semiconductor layers 2218. The third semiconductor layers 2216 may each be configured as the channel (region) of a corresponding transistor structure, while the adjacent pair of second/fourth semiconductor layers 2214/2218 may be later removed or replaced with source/drain regions of the transistor structure, which will be discussed in further detail below. As such, the third semiconductor layer 2216, the second semiconductor layer 2214, and the fourth semiconductor layer 2218 may sometimes be referred to as “channel layer/region 2216,” “sacrificial layer 2214,” and “sacrificial layer 2218,” respectively, in the following discussions. Based on such a rationale, the number of sandwiched channel layers 2216 included in the stack 2010 (e.g., two in the example of FIG. 22) may correspond to the number of transistor structures vertically stacked on top of one another.

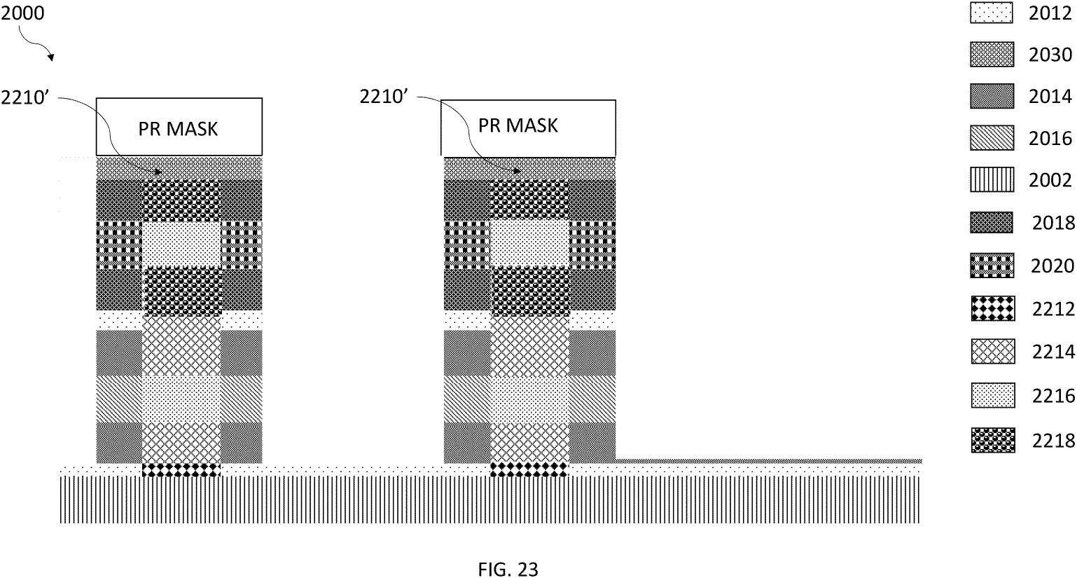

Corresponding to operation 1908 of FIG. 19, FIG. 23 is a cross-sectional view of the semiconductor device 2000 in which the stack 2010 is further patterned, in accordance with various embodiments. The operation 1908 is substantially similar to the operation 108 of the method 100, and thus, the description is not repeated. By performing the operation 1908, a number of wrapped vertical structure 2210' each including a corresponding vertical structure 2210 surrounded by the remaining dielectric materials are formed.

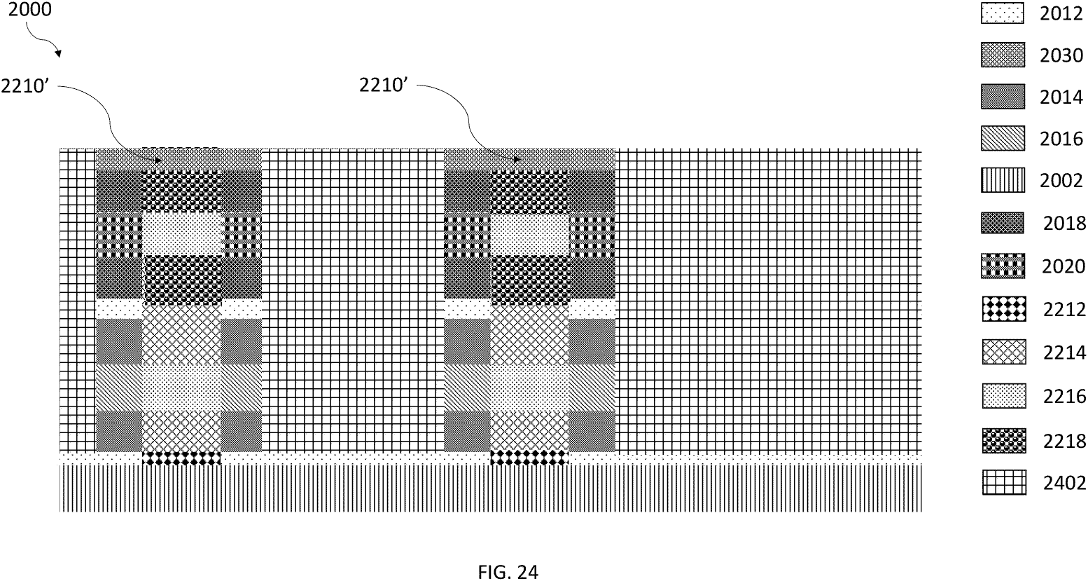

Corresponding to operation 1910 of FIG. 19, FIG. 24 is a cross-sectional view of the semiconductor device 2000 in which the patterned stack 2010 is filled with a first filling dielectric material 2402, in accordance with various embodiments. The operation 1910 is substantially similar to the operation 110 of the method 100, and thus, the description is not repeated.

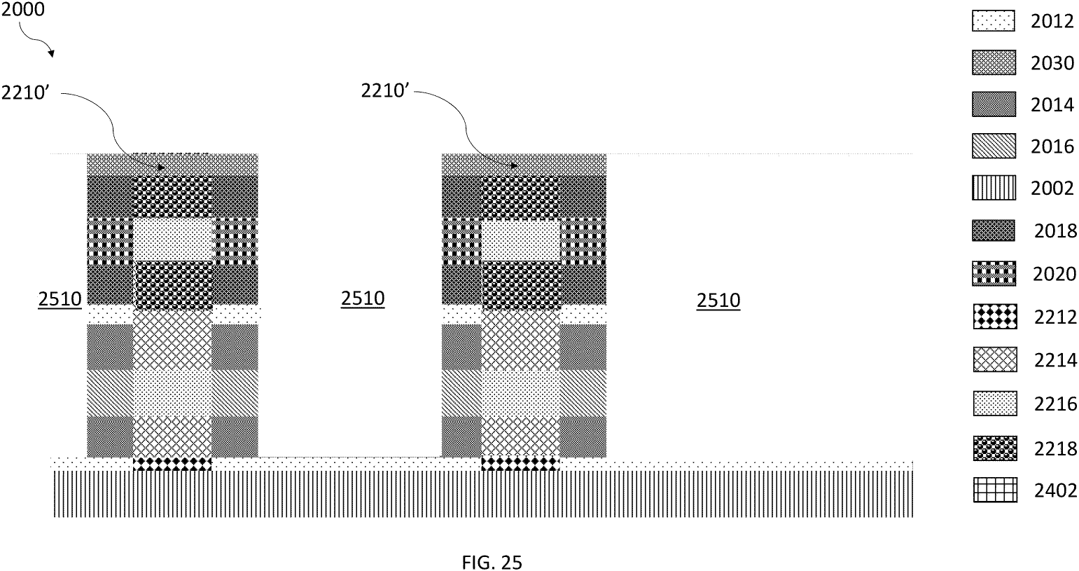

Corresponding to operation 1912 of FIG. 19, FIG. 25 is a cross-sectional view of the semiconductor device 2000 in which the first filling dielectric material 2402 is patterned, thereby exposing a portion of each of the wrapped vertical structures 2210', in accordance with various embodiments. The operation 1912 is substantially similar to the operation 112 of the method 100, and thus, the description is not repeated.

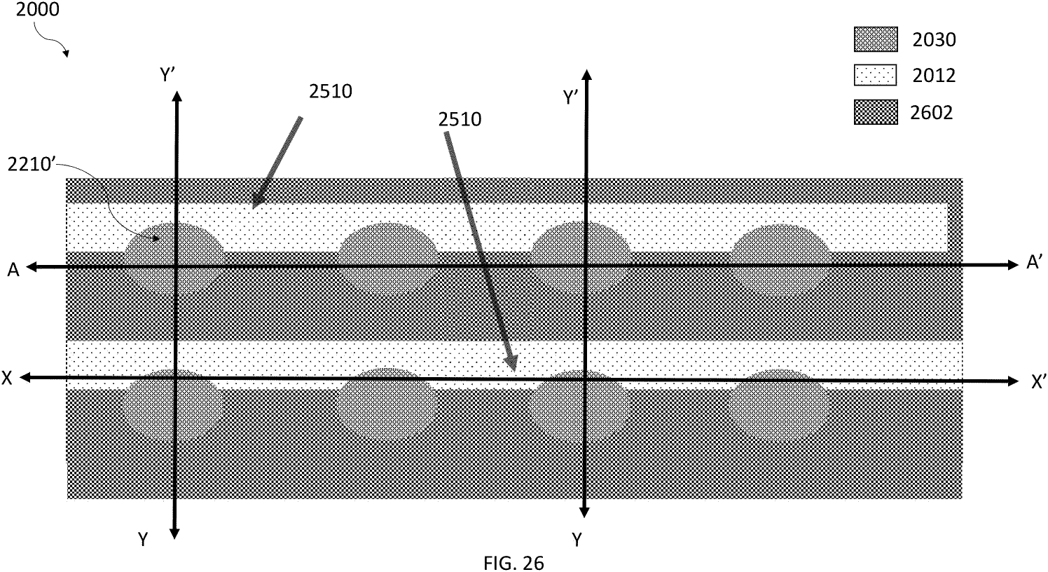

To illustrate the exposed portion of each of the wrapped vertical structures 2210', a top view of the semiconductor device 2000 is shown in FIG. 26. As illustrated, a patternable layer (e.g., a photoresist mask) 2602 can be formed over the workpiece, e.g., with the hardmask layer 2030 and first filling dielectric material 2402 disposed therebelow. Further, the patternable layer 2602 can have a pattern (e.g., one or more openings) exposing a portion of each of the wrapped vertical structures 2210' and portions of the first filling dielectric material 2402. By performing at least one etching process with the patternable layer 2602 as a mask, one or more openings 2510 can be formed, which can expose a portion of a sidewall of each of the wrapped vertical structures 2210'. In FIG. 26, along cross-section X-X′, the corresponding portion of each of the wrapped vertical structures 2210' is exposed by the opening 2510, while, along cross-section A-A′, the corresponding portion of each of the wrapped vertical structures 2210' may still remain covered by the first filling dielectric material 2402.

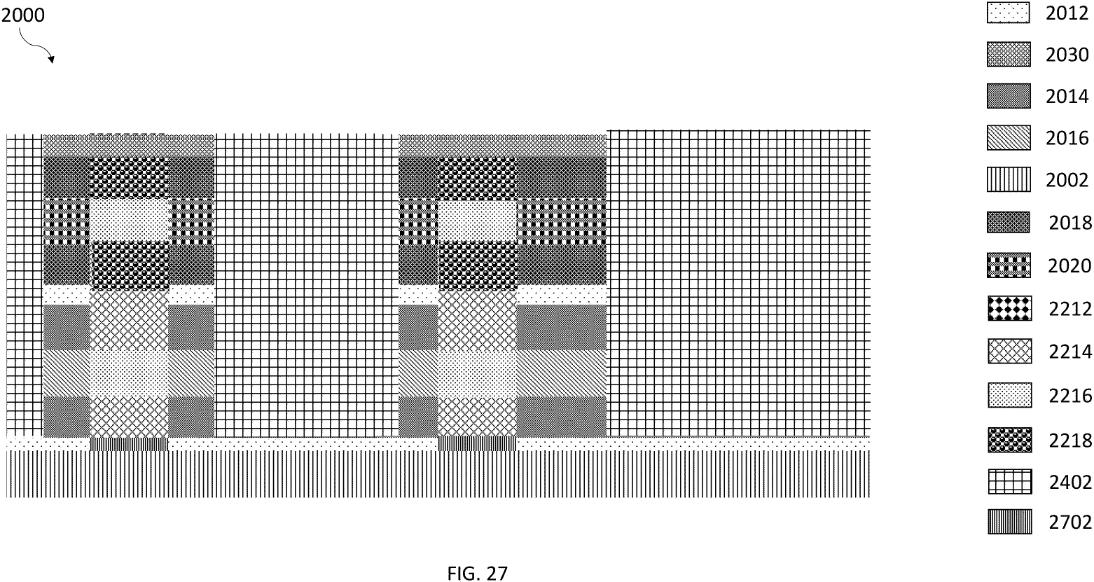

Corresponding to operation 1914 of FIG. 19, FIG. 27 is a cross-sectional view of the semiconductor device 2000 in which an isolation dielectric material 2702 is formed below each of the wrapped vertical structures 2210', in accordance with various embodiments. It should be noted that the cross-sectional view of FIG. 27 is cut along cross-section A-A′, as illustrated in the top view of FIG. 26. The operation 1914 is substantially similar to the operation 114 of the method 100, and thus, the description is not repeated.

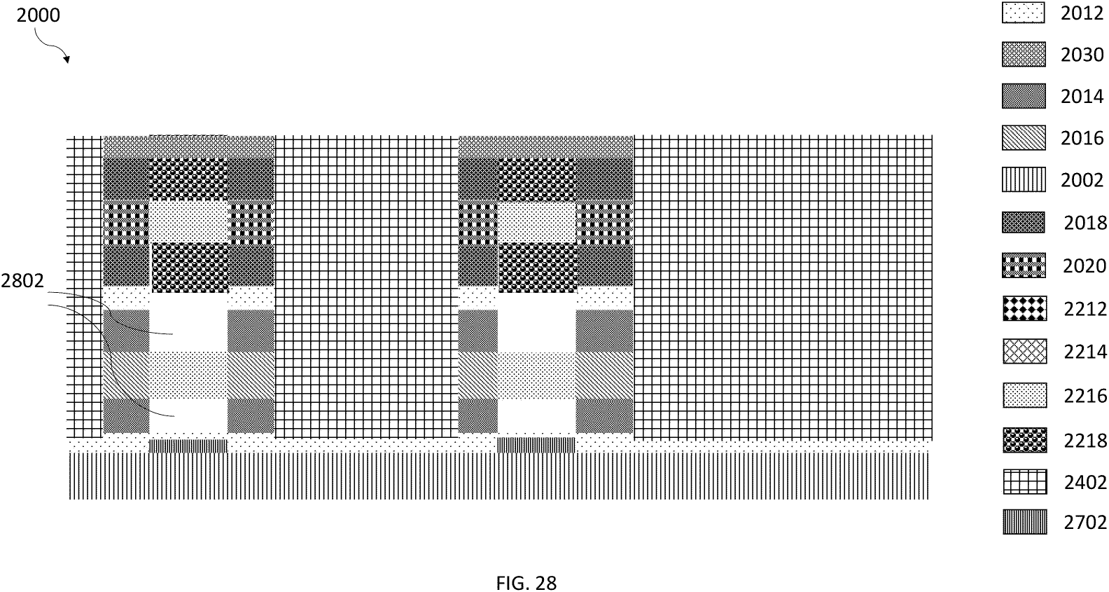

Corresponding to operation 1916 of FIG. 19, FIG. 28 is a cross-sectional view of the semiconductor device 2000 in which the second semiconductor layers 2214 are removed, in accordance with various embodiments. It should be noted that the cross-sectional view of FIG. 12 is cut along cross-section A-A′, as illustrated in the top view of FIG. 26.

The second semiconductor layers 2214 may be removed by a selective etching process, which leaves the third semiconductor layers 2216 and fourth semiconductor layers 2218 substantially intact. As such, a top surface and bottom surface of the lower third semiconductor layer 2216 are exposed by first cavities 2802, respectively, while a sidewall of the lower third semiconductor layer 2216 may remain surrounded by the third dielectric material 2016. Stated another way, upon removing the second semiconductor layers 2214, each of the wrapped vertical structures 2210' can include a number of first cavities 2802 corresponding to the number of second semiconductor layers 2214 included in the wrapped vertical structure 2210'. The exposed top and bottom surfaces may be utilized to epitaxially grow source and drain regions, respectively, and the covering third dielectric material 2016 may be replaced with a gate (structure), which will be discussed in further detail below.

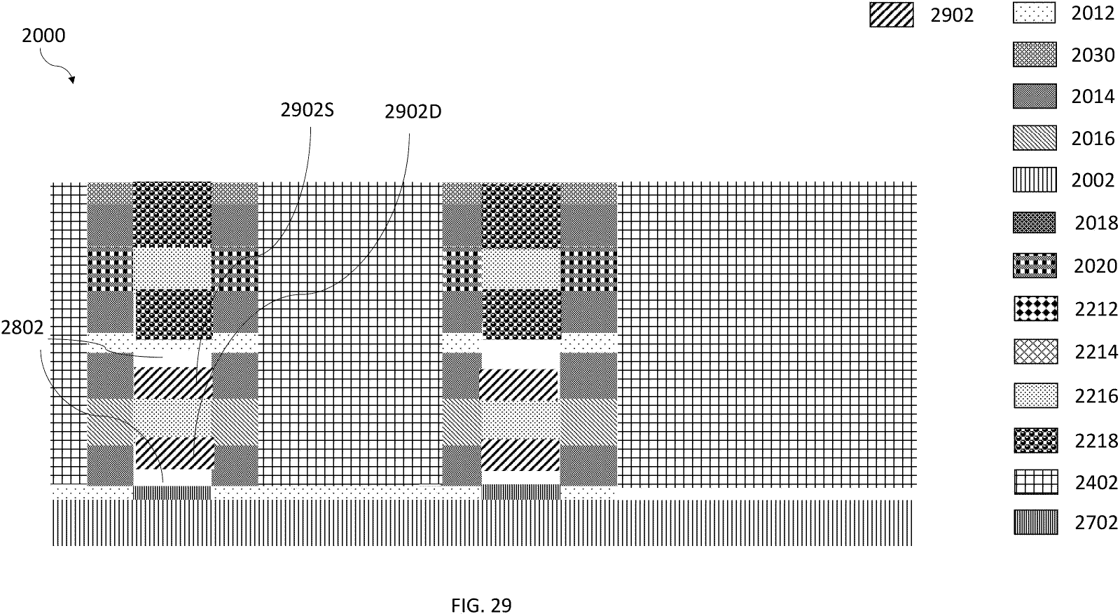

Corresponding to operation 1918 of FIG. 19, FIG. 29 is a cross-sectional view of the semiconductor device 2000 in which a number of self-aligned first source/drain regions 2902 are formed, in accordance with various embodiments. It should be noted that the cross-sectional view of FIG. 29 is cut along cross-section A-A′, as illustrated in the top view of FIG. 26.

After forming the first cavities 2802, the first source/drain regions 2902 can formed by epitaxially growing a semiconductor material from the exposed lower third semiconductor layers 2216. Specifically, the first source/drain regions 2902 can be grown from the top and bottom surfaces of the lower third semiconductor layers 2216. As such, the lower third semiconductor layer 2216 may be vertically sandwiched by a pair of the first source/drain regions 2902, one of which may operatively serve as a source region 2902S and the other of which may operatively serve as a drain region 2902D, as shown in the cross-sectional view of FIG. 29. The growth process includes any of the following suitable methods such as metal-organic CVD (MOCVD), molecular beam epitaxy (MBE), liquid phase epitaxy (LPE), vapor phase epitaxy (VPE), selective epitaxial growth (SEG), the like, or a combination thereof.

In various embodiments, the first source/drain regions 2902 may be implanted with dopants to form first doped source/drain regions 2902 followed by an annealing process. For example, when the resulting transistor structure is an n-type transistor, the first doped source/drain regions 2902 can include silicon carbide (SiC), silicon phosphorous (SiP), phosphorous-doped silicon carbon (SiCP), or the like. When the resulting transistor structure is a p-type transistor, the first source/drain regions 2902 can include SiGe, and a p-type impurity such as boron or indium. In some embodiments, the first source/drain regions 2902 may be in situ doped during their growth.

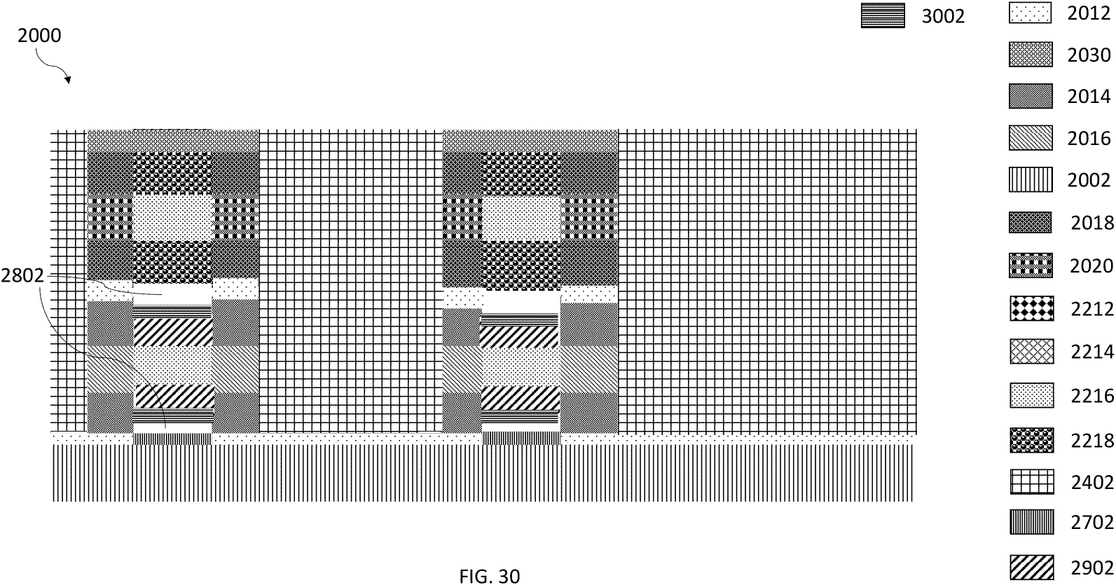

Corresponding to operation 1920 of FIG. 19, FIG. 30 is a cross-sectional view of the semiconductor device 2000 in which a number of first silicide layers 3002 are formed, in accordance with various embodiments. It should be noted that the cross-sectional view of FIG. 30 is cut along cross-section A-A′, as illustrated in the top view of FIG. 26.

Each of the first silicide layers 3002 can be formed at or near the exposed surface of a corresponding one of the first source/drain regions 2902. As such, the lower third semiconductor layer 2216 may be vertically sandwiched further by a pair of the first silicide layers 3002. In some embodiments, after forming the first silicide layers 3002, the first cavities 2802 may still remain, as shown in FIG. 30. The first silicide layers 3002 can include chemical compounds that can be formed within, between or near a semiconductor material, such as the lower third semiconductor layer 2216, and a metal. For example, the first silicide layer 3002 can be formed when a layer of metal that is suitable for forming a binary compound with silicon upon annealing, is in a physical contact with Si material and is exposed to a temperature level sufficiently high (e.g., in an annealing process) to form the silicide region at or near the interface of the Si and the metal.

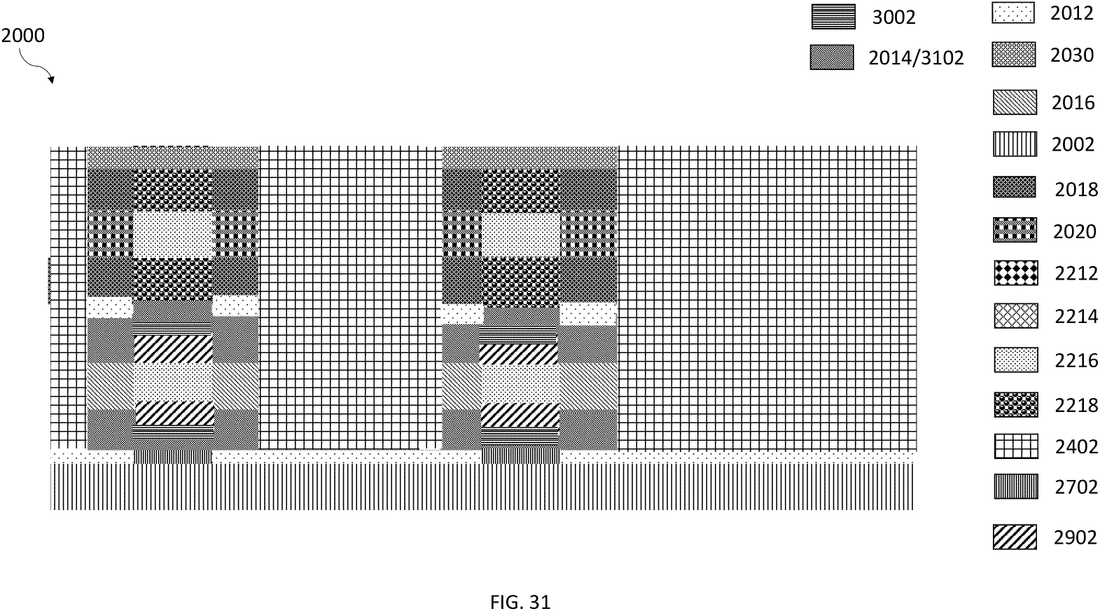

Corresponding to operation 1922 of FIG. 19, FIG. 31 is a cross-sectional view of the semiconductor device 2000 in which the first cavities 2802 are each filled with a second filling dielectric material 3102, in accordance with various embodiments. It should be noted that the cross-sectional view of FIG. 31 is cut along cross-section A-A′, as illustrated in the top view of FIG. 26.

The first cavities 2802 may each be fully filled with the second filling dielectric material 3102, as shown in FIG. 31. However, it should be understood that the first cavities 2802 may each be partially filled with the second filling dielectric material 3102, while remaining within the scope of the present disclosure. As such, the wrapped vertical structure 2210' can include one or more air gaps therein. In some embodiments, the second filling dielectric material 3102 is substantially similar to the second dielectric material 2014. Accordingly, the second filling dielectric material 3102 includes at least one insulation material, which may be an oxide, such as a silicon oxide, a nitride, the like, or combinations thereof, and may be formed by a high density plasma chemical vapor deposition (HDP-CVD), a flowable CVD (FCVD) (e.g., a CVD-based material deposition in a remote plasma system and post curing to make it convert to another material, such as an oxide), the like, or combinations thereof. After the deposition of the second filling dielectric material 3102, a CMP process may be performed.

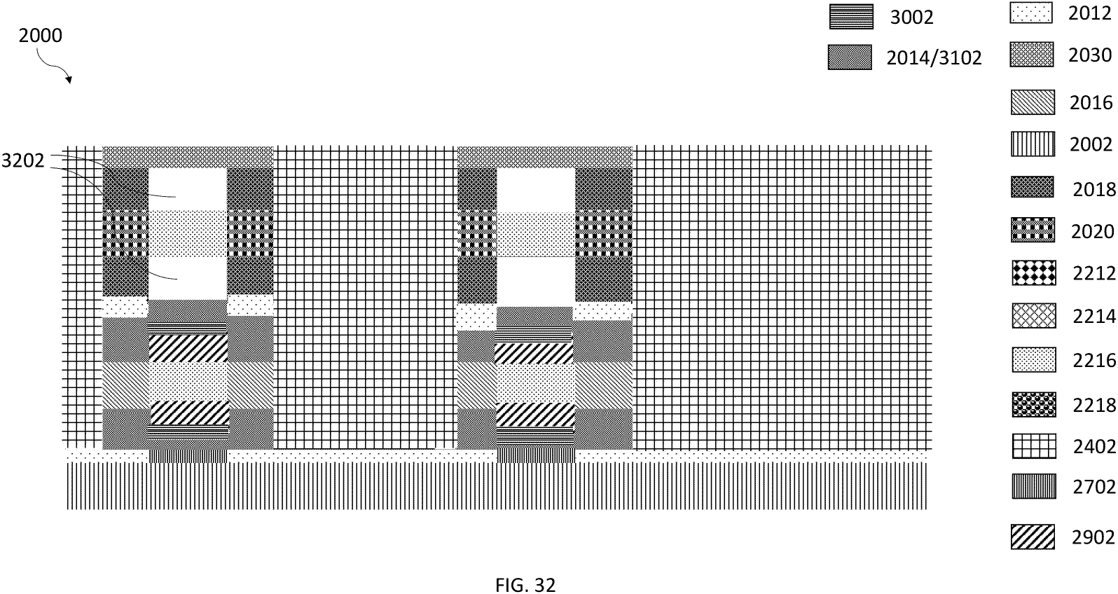

Corresponding to operation 1924 of FIG. 19, FIG. 32 is a cross-sectional view of the semiconductor device 2000 in which the fourth semiconductor layers 2218 are removed, in accordance with various embodiments. It should be noted that the cross-sectional view of FIG. 32 is cut along cross-section A-A′, as illustrated in the top view of FIG. 26.

The fourth semiconductor layers 2218 may be removed by a selective etching process, which leaves the upper third semiconductor layer 2216 substantially intact. As such, a top surface and bottom surface of the upper third semiconductor layer 2216 are exposed by second cavities 3202, respectively, while a sidewall of the upper third semiconductor layer 2216 may remain surrounded by the fourth dielectric material 2018. Stated another way, upon removing the fourth semiconductor layers 2218, each of the wrapped vertical structures 2210' can include a number of second cavities 3202 corresponding to the number of fourth semiconductor layers 2218 included in the wrapped vertical structure 2210'. The exposed top and bottom surfaces may be utilized to epitaxially grow source and drain regions, respectively, and the covering fourth dielectric material 2018 may be replaced with a gate (structure), which will be discussed in further detail below.

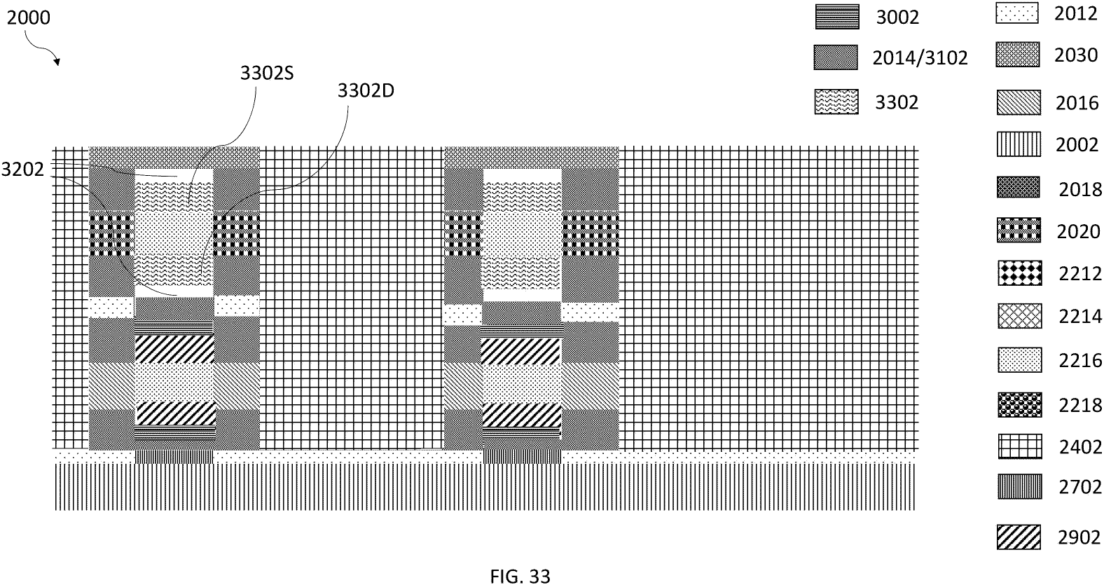

Corresponding to operation 1926 of FIG. 19, FIG. 33 is a cross-sectional view of the semiconductor device 2000 in which a number of self-aligned second source/drain regions 3302 are formed, in accordance with various embodiments. It should be noted that the cross-sectional view of FIG. 33 is cut along cross-section A-A′, as illustrated in the top view of FIG. 26.

After forming the second cavities 3202, the second source/drain regions 3302 can formed by epitaxially growing a semiconductor material from the exposed upper third semiconductor layers 2216. Specifically, the second source/drain regions 3302 can be grown from the top and bottom surfaces of the upper third semiconductor layers 2216. As such, the upper third semiconductor layer 2216 may be vertically sandwiched by a pair of the second source/drain regions 3302, one of which may operatively serve as a source region 3302S and the other of which may operatively serve as a drain region 3302D, as shown in the cross-sectional view of FIG. 33. The growth process includes any of the following suitable methods such as metal-organic CVD (MOCVD), molecular beam epitaxy (MBE), liquid phase epitaxy (LPE), vapor phase epitaxy (VPE), selective epitaxial growth (SEG), the like, or a combination thereof.

In various embodiments, the second source/drain regions 3302 may be implanted with dopants to form second doped source/drain regions 3302 followed by an annealing process. For example, when the resulting transistor structure is an n-type transistor, the second doped source/drain regions 3302 can include silicon carbide (SiC), silicon phosphorous (SiP), phosphorous-doped silicon carbon (SiCP), or the like. When the resulting transistor structure is a p-type transistor, the second source/drain regions 3302 can include SiGe, and a p-type impurity such as boron or indium. In some embodiments, the second source/drain regions 3302 may be in situ doped during their growth. In various embodiments, the first second doped source/drain regions 2902 and the second doped source/drain regions 3302 may have respectively different conductive types, such that a complementary transistor structure (e.g., a p-type transistor and an n-type transistor vertically stacked on top of one another) can be formed.

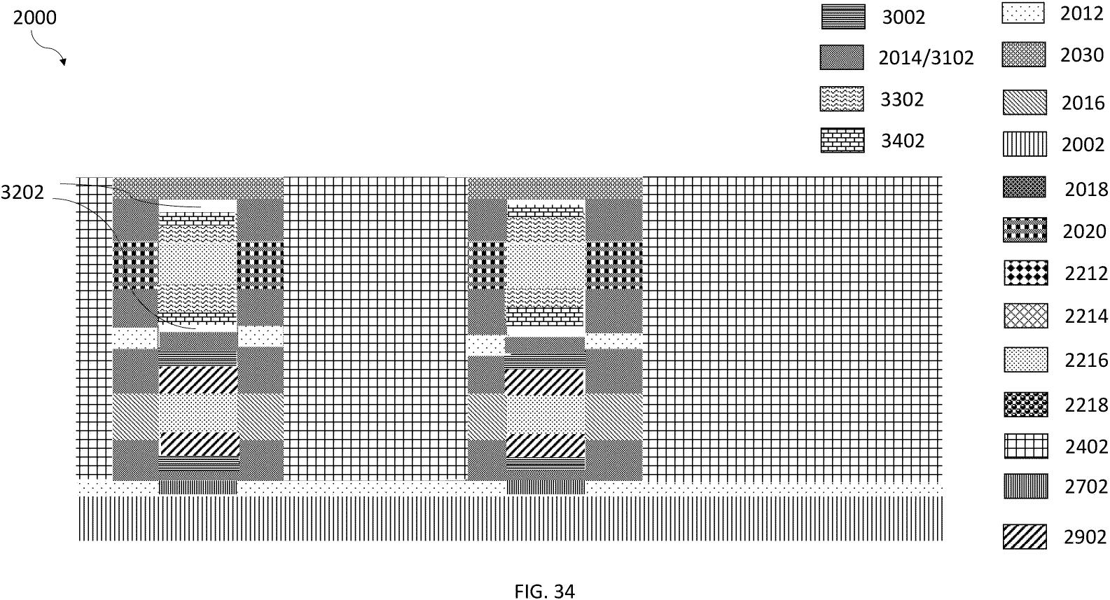

Corresponding to operation 1928 of FIG. 19, FIG. 34 is a cross-sectional view of the semiconductor device 2000 in which a number of second silicide layers 3402 are formed, in accordance with various embodiments. It should be noted that the cross-sectional view of FIG. 34 is cut along cross-section A-A′, as illustrated in the top view of FIG. 26.

Each of the second silicide layers 3402 can be formed at or near the exposed surface of a corresponding one of the second source/drain regions 3302. As such, the upper third semiconductor layer 2216 may be vertically sandwiched further by a pair of the second silicide layers 3402. In some embodiments, after forming the second silicide layers 3402, the second cavities 3202 may still remain, as shown in FIG. 34. The second silicide layers 3402 can include chemical compounds that can be formed within, between or near a semiconductor material, such as the upper third semiconductor layer 2216, and a metal. For example, the second silicide layer 3402 can be formed when a layer of metal that is suitable for forming a binary compound with silicon upon annealing, is in a physical contact with Si material and is exposed to a temperature level sufficiently high (e.g., in an annealing process) to form the silicide region at or near the interface of the Si and the metal.

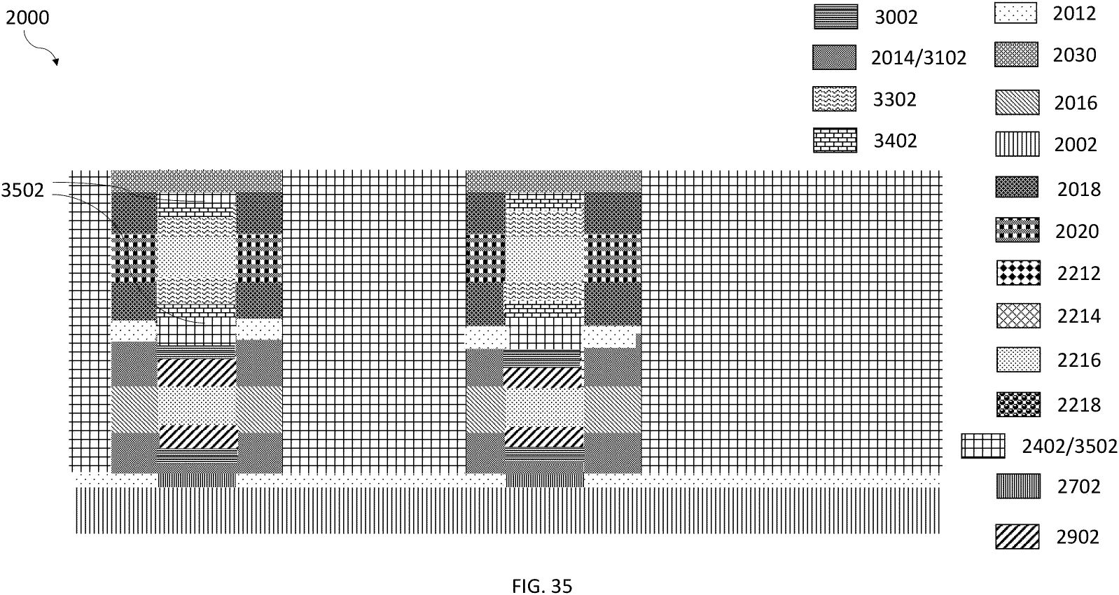

Corresponding to operation 1930 of FIG. 19, FIG. 35 is a cross-sectional view of the semiconductor device 2000 in which the second cavities 3202 are each filled with a third filling dielectric material 3502, in accordance with various embodiments. It should be noted that the cross-sectional view of FIG. 35 is cut along cross-section A-A′, as illustrated in the top view of FIG. 26.

The second cavities 3202 may each be fully filled with the third filling dielectric material 3502, as shown in FIG. 35. However, it should be understood that the second cavities 3202 may each be partially filled with the third filling dielectric material 3502, while remaining within the scope of the present disclosure. As such, the wrapped vertical structure 2210' can include one or more air gaps therein. In some embodiments, the third filling dielectric material 3502 is substantially similar to the first filling dielectric material 2402. Accordingly, the third filling dielectric material 3502 includes at least one insulation material, which may be an oxide, such as a silicon oxide, a nitride, the like, or combinations thereof, and may be formed by a high density plasma chemical vapor deposition (HDP-CVD), a flowable CVD (FCVD) (e.g., a CVD-based material deposition in a remote plasma system and post curing to make it convert to another material, such as an oxide), the like, or combinations thereof. After the deposition of the trhid filling dielectric material 3502, a CMP process may be performed.

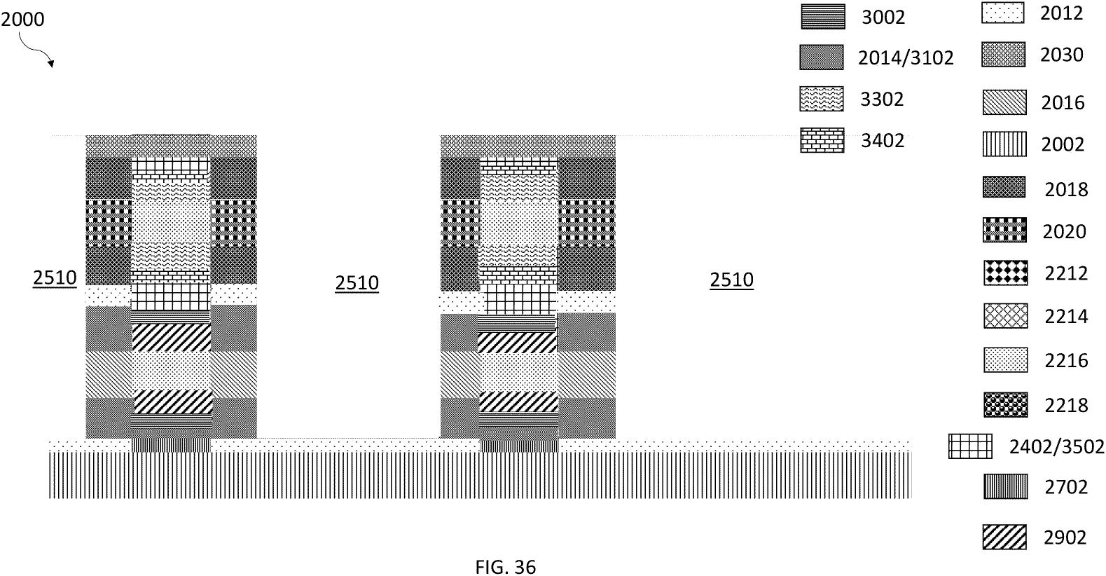

Corresponding to operation 1932 of FIG. 19, FIG. 36 is a cross-sectional view of the semiconductor device 2000 in which the openings 2510 (FIG. 26) are exposed again, in accordance with various embodiments. It should be noted that the cross-sectional view of FIG. 36 is cut along cross-section X-X′, as illustrated in the top view of FIG. 26. The operation 1932 is substantially similar to the operation 124 of the method 100, and thus, the description is not repeated.

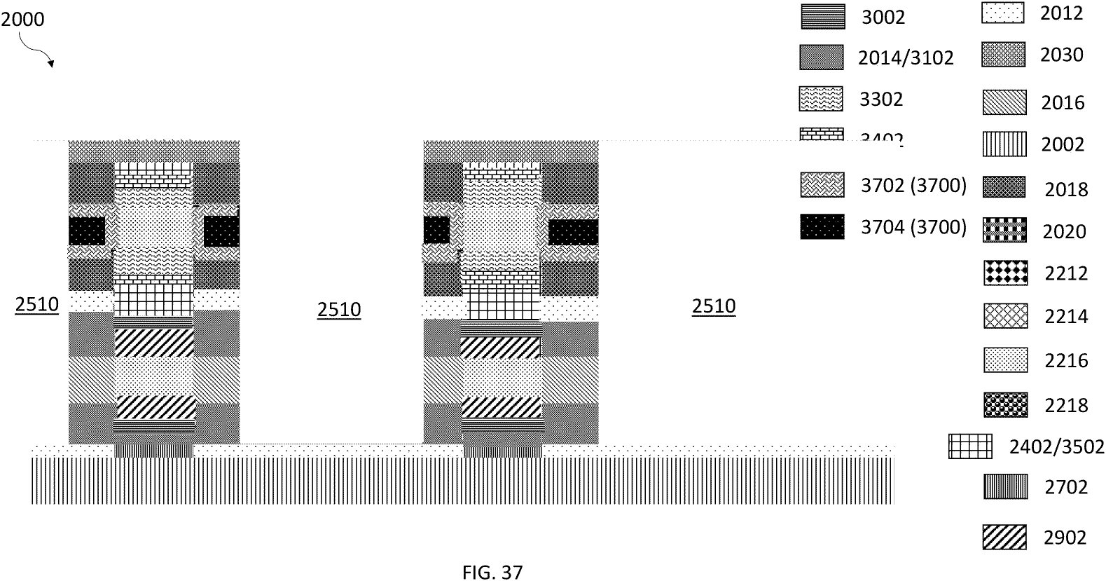

Corresponding to operation 1934 of FIG. 19, FIG. 37 is a cross-sectional view of the semiconductor device 2000 including a number of upper gates 3700 (each of which includes an upper gate dielectric 3702 and an upper gate conductor 3704), in accordance with various embodiments. It should be noted that the cross-sectional view of FIG. 37 is cut along cross-section X-X′, as illustrated in the top view of FIG. 26. The operation 1934 is substantially similar to the operation 126 of the method 100, and thus, the description is not repeated.

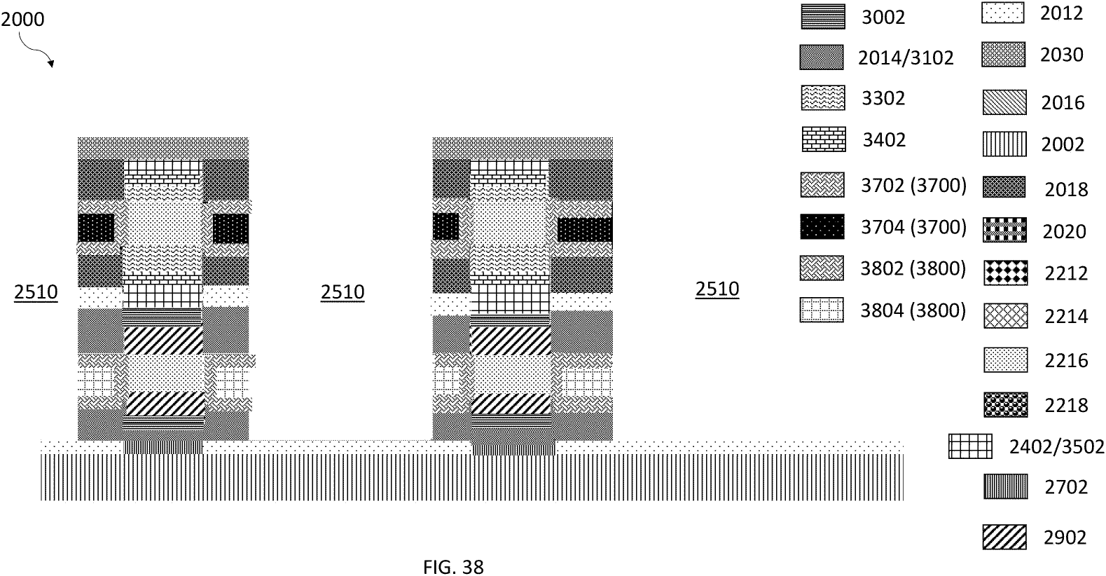

Corresponding to operation 1936 of FIG. 19, FIG. 38 is a cross-sectional view of the semiconductor device 2000 including a number of lower gates 3800 (each of which includes a lower gate dielectric 3802 and a lower gate conductor 3804), in accordance with various embodiments. It should be noted that the cross-sectional view of FIG. 38 is cut along cross-section X-X′, as illustrated in the top view of FIG. 26. The operation 1936 is substantially similar to the operation 126 of the method 100, and thus, the description is not repeated.

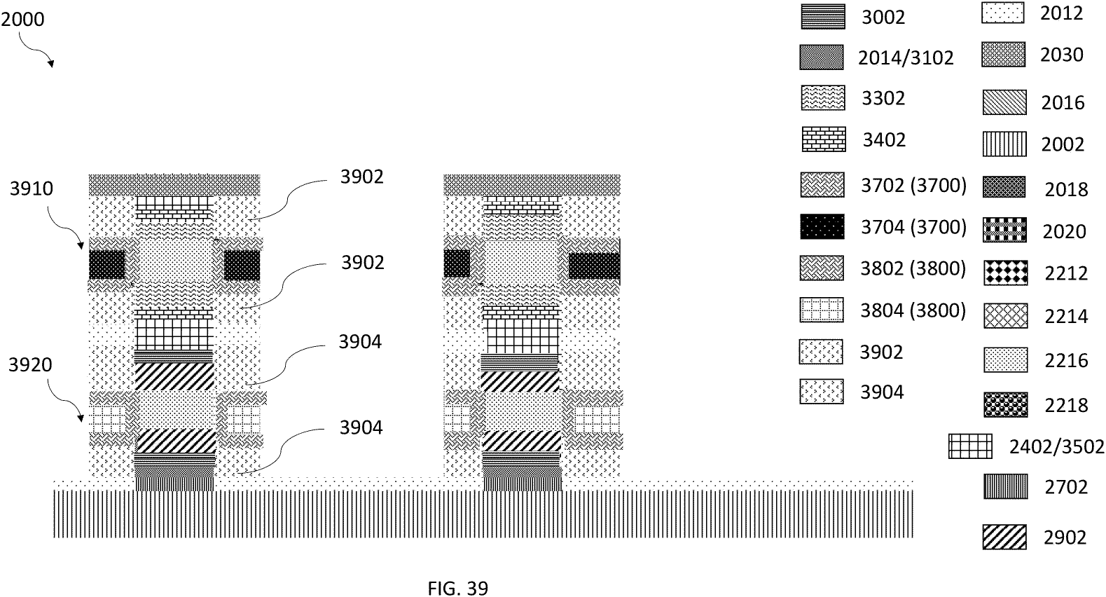

Corresponding to operation 1938 of FIG. 19, FIG. 39 is a cross-sectional view of the semiconductor device 2000 including a number of upper source/drain electrodes 3902 and a number of lower source/drain electrodes 3904, in accordance with various embodiments. It should be noted that the cross-sectional view of FIG. 39 is cut along cross-section X-X′, as illustrated in the top view of FIG. 26. The operation 1938 is substantially similar to the operation 128 of the method 100, and thus, the description is not repeated.

In various embodiments, through performing at least some of the operations of the method 1900, a number of vertical transistors stacked on top of one another can be formed. For example in FIG. 39, a first transistor 3910 and a second transistor 3920 are formed over the substrate 2002. Each of the first transistor 3910 and second transistor 3920 has a corresponding third semiconductor layer 2216 (functioning as channel), a corresponding gate 3700/3800 surrounding the channel, and a pair of source/drain regions 2902/3302 disposed above and below the channel, respectively. As the pair of source/drain regions 3302 of the first transistor 3910 and the pair of source/drain regions 3302 of the second transistor 3920 are formed (e.g., doped) separately while the channel are formed as intrinsic, the first transistor 3910 and second transistor 3920 may have different conductive types.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

Various techniques have been described as multiple discrete operations to assist in understanding the various embodiments. The order of description should not be construed as to imply that these operations are necessarily order dependent. Indeed, these operations need not be performed in the order of presentation. Operations described may be performed in a different order than the described embodiment. Various additional operations may be performed and/or described operations may be omitted in additional embodiments.

“Substrate” or “target substrate” as used herein generically refers to an object being processed in accordance with the invention. The substrate may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate is not limited to any particular base structure, underlying layer or overlying layer, patterned or un-patterned, but rather, is contemplated to include any such layer or base structure, and any combination of layers and/or base structures. The description may reference particular types of substrates, but this is for illustrative purposes only.

Those skilled in the art will also understand that there can be many variations made to the operations of the techniques explained above while still achieving the same objectives of the invention. Such variations are intended to be covered by the scope of this disclosure. As such, the foregoing descriptions of embodiments of the invention are not intended to be limiting. Rather, any limitations to embodiments of the invention are presented in the following claims.

What is claimed is:

1. A device structure, comprising:
a channel region having a first surface facing an underlying substrate and a second surface opposite to the first surface;
a gate at least partially surrounding the channel region, the gate including a gate dielectric and a gate conductor, the gate dielectric separating the gate conductor from the channel region; and
self-aligned source and drain regions (S/D regions) contacting the first and second surfaces, respectively.

2. The device structure of claim 1, further comprising source and drain electrodes (S/D electrodes) contacting the respective self-aligned S/D regions, the S/D electrodes vertically adjacent the gate dielectric.

3. The device structure of claim 2, wherein the S/D electrodes surround the respective self-aligned S/D regions.

4. The device structure of claim 1, wherein the channel region comprises an undoped semiconductor material.

5. The device structure of claim 1, wherein the self-aligned S/D regions each comprise a doped semiconductor material.

6. The device structure of claim 1, wherein the gate conductor is formed as a ring structure, with its inner sidewall, top surface, and bottom surface being in contact with the gate dielectric of the gate.

7. The device structure of claim 1, further comprising:
a second channel region having a third surface facing the underlying substrate and a fourth surface opposite to the third surface;
a second gate at least partially surrounding the second channel region, the second gate including a second gate dielectric and a second gate conductor, the second gate dielectric separating the second gate conductor from the second channel region; and
second self-aligned source and drain regions (S/D regions) contacting the third and fourth surfaces, respectively.

8. The device structure of claim 7, wherein the first channel region and second channel region each comprise an undoped semiconductor material.

9. The device structure of claim 8, wherein the first self-aligned S/D regions each comprise a first doped semiconductor material with a first conductive type, and the second self-aligned source and drain regions (S/D regions) each comprise a second doped semiconductor material with a second conductive type.

10. The device structure of claim 9, wherein the gate conductor has the first conductive type, and the second gate conductor has the second conductive type.

11. A device structure, comprising:
a first device comprising:
a first channel region having a first surface facing an underlying substrate and a second surface opposite to the first surface;
a first gate at least partially surrounding the first channel region, the first gate adjacent a third surface of the first channel region, the third surface extending between the first and second surfaces, the first gate including a first gate dielectric and a first gate conductor, the first gate dielectric separating the first gate conductor from the first channel region; and
first self-aligned source and drain regions (S/D regions) contacting the first and second surfaces, respectively; and
a second device isolated from the first device and comprising:
a second channel region having a fourth surface facing the underlying substrate and a fifth surface opposite to the fourth surface;
a second gate at least partially surrounding the second channel region, the second gate adjacent a sixth surface of the second channel region, the sixth surface extending between the fourth and fifth surfaces, the second gate including a second gate dielectric and a second gate conductor, the second gate dielectric separating the second gate conductor from the second channel region; and
second self-aligned source and drain regions (S/D regions) contacting the fourth and fifth surfaces, respectively.

12. The device structure of claim 11, wherein the first and second devices have a same conductive type.

13. The device structure of claim 11, wherein the first and second channel regions each comprise an undoped semiconductor material.

14. The device structure of claim 11, wherein the first and second self-aligned S/D regions each comprise a doped semiconductor material.

15. The device structure of claim 11, wherein the first gate conductor is formed as a first ring structure, with its inner sidewall, top surface, and bottom surface being in contact with the first gate dielectric, and wherein the second gate conductor of the gate is formed as a second ring structure, with its inner sidewall, top surface, and bottom surface being in contact with the second gate dielectric.

16. The device structure of claim 11, wherein:
the first device further comprises first source and drain electrodes (S/D electrodes) contacting the respective first self-aligned S/D regions, the first S/D electrodes vertically adjacent the first gate dielectric; and
the second device further comprises second source and drain electrodes (S/D electrodes) contacting the respective second self-aligned S/D regions, the second S/D electrodes vertically adjacent the second gate dielectric.

17. The device structure of claim 16, wherein the first S/D electrodes are above and below the first gate conductor, respectively, and the second S/D electrodes are above and below the second gate conductor, respectively.

18. A method for fabricating semiconductor devices, comprising:
forming a channel region over a substrate as one of a series of epitaxially-grown layers;
forming source and drain regions (S/D regions) by epitaxially growing semiconductor layers on opposing sides of the channel region; and
forming a gate at least partially surrounding the channel region, the gate comprising a gate conductor and a gate dielectric, the gate dielectric separating the gate conductor from the channel region.

19. The method of claim 18, wherein the channel region comprises an undoped semiconductor material.

20. The method of claim 18, further comprising forming source and drain contacts at least partially surrounding respective source and drain regions, the gate dielectric separating the gate conductor from the source and drain contacts.
